(19) United States
(12) Patent Application Publication
(10) Pub. No.: US 2025/0380524 A1
(43) Pub. Date: Dec. 11, 2025

(54) IMAGE SENSOR AND METHOD OF FABRICATING THE SAME

(71) Applicant: SAMSUNG ELECTRONICS CO., LTD., Suwon-si (KR)

(72) Inventor: Kook Tae Kim, Suwon-si (KR)

(21) Appl. No.: 19/087,164

(22) Filed: Mar. 21, 2025

(30) Foreign Application Priority Data
Jun. 5, 2024 (KR) 10-2024-0073841

(51) Int. Cl. H10F 39/00; H10F 39/18

(52) U.S. Cl. CPC H10F 39/807; H10F 39/014; H10F 39/182

(57) ABSTRACT

An image sensor may include a substrate having first and second surfaces and including a plurality of pixel regions and a device isolation pattern interposed between the pixel regions. The device isolation pattern may include an intervening region and an intersecting region. In the intervening region, the device isolation pattern may include a gapfill insulating pattern, a conductive liner in contact with the gapfill insulating pattern, an intervening insulating pattern in contact with the conductive liner, a first insulating liner in contact with the substrate, and a second insulating liner in contact with the intervening insulating pattern. An interface between the conductive liner and the intervening insulating pattern may include a curved surface. A length of the second insulating liner may be 80% to 120% of a length of the bottommost point of the conductive liner, when measured from the second surface of the substrate.

### CROSS-REFERENCE TO RELATED APPLICATION

This U.S. non-provisional patent application claims priority under 35 U.S.C. § 119 to Korean Patent Application No. 10-2024-0073841, filed on Jun. 5, 2024, in the Korean Intellectual Property Office, the entire contents of which are hereby incorporated by reference.

### BACKGROUND

The present disclosure relates to an image sensor and a method of fabricating the same, and in particular, to a complementary metal oxide semiconductor (CMOS) image sensor and a method of fabricating the same.

An image sensor is a semiconductor device converting an optical image to electric signals. With the recent development of the computer and communication industries, there is an increasing demand for high-performance image sensors in a variety of applications such as digital cameras, camcorders, personal communication systems, gaming machines, security cameras, micro-cameras for medical applications, and/or robots. The image sensor may be classified into two types: a charge coupled device (CCD) type and a complementary metal-oxide-semiconductor (CMOS) type. In general, the CMOS-type image sensor is called “CIS”. The CIS device includes a plurality of two-dimensionally-arranged pixels. Each of the pixels includes a photodiode (PD) that coverts incident light into an electrical signal. The plurality of pixels may be defined by a deep device isolation pattern.

### SUMMARY

Implementations of the present disclosure include an image sensor with a high yield and a method of fabricating the same.

Implementations of the present disclosure include an image sensor with a high sensitivity and a method of fabricating the same.

In general, in some aspects, the present disclosure is directed to an image sensor that includes a substrate having a first surface and a second surface, which are opposite to each other, and including a plurality of pixel regions, and a device isolation pattern extended from the first surface into the substrate and interposed between the pixel regions. The device isolation pattern may include an intervening region and an intersecting region. In the intervening region, the device isolation pattern may include a gapfill insulating pattern, a conductive liner in contact with the gapfill insulating pattern, an intervening insulating pattern in contact with the conductive liner, a first insulating liner in contact with the substrate, and a second insulating liner in contact with the intervening insulating pattern. An interface between the conductive liner and the intervening insulating pattern may include a curved surface. A distance of the second insulating liner from the second surface of the substrate may be 80% to 120% of a distance of the bottommost point of the conductive liner from the second surface of the substrate.

In general, in some aspects, the present disclosure is directed to an image sensor that includes a substrate having a first surface and a second surface, which are opposite to each other, and including a plurality of pixel regions, an anti-reflection layer on the substrate, and a device isolation pattern extended from the first surface into the substrate and interposed between the pixel regions. The device isolation pattern may include an intervening region and an intersecting region. In the intersecting region, the device isolation pattern may include a first insulating liner in contact with the substrate, a second insulating liner on the first insulating liner, a conductive liner in contact with the second insulating liner, an intervening insulating pattern in contact with the conductive liner and the second insulating liner, and a gap portion defined in a center portion of the intersecting region. A bottom surface of the conductive liner may include a curved surface, and the gap portion may include an air gap or the same material as the anti-reflection layer.

In general, in some aspects, the present disclosure is directed to an image sensor that includes a substrate having a first surface and a second surface, which are opposite to each other, and including a plurality of pixel regions, a transfer gate disposed on the first surface, an anti-reflection layer disposed on the second surface, color filters on the anti-reflection layer, a device isolation pattern extended from the first surface into the substrate and interposed between the pixel regions. The device isolation pattern may include an intervening region and an intersecting region. In the intervening region, the device isolation pattern may include a gapfill insulating pattern, a conductive liner in contact with the gapfill insulating pattern, an intervening insulating pattern in contact with a bottom surface of the conductive liner, a first insulating liner in contact with the substrate, and a second insulating liner in contact with the intervening insulating pattern. In the intersecting region, the device isolation pattern may include a first insulating liner in contact with the substrate, a second insulating liner on the first insulating liner, a conductive liner in contact with the second insulating liner, and a gap portion defined in a center portion of the intersecting region. The bottom surface of the conductive liner may include a curved surface, and the first and second insulating liners may include different materials having different etching rates from each other.

### BRIEF DESCRIPTION OF THE DRAWINGS

FIG. 1 is a block diagram schematically illustrating an image sensor according to some implementations.

FIG. 2 is a circuit diagram illustrating an active pixel sensor array of an image sensor according to some implementations.

FIG. 3 is a plan view illustrating an image sensor according to some implementations.

FIG. 4A is a sectional view taken along a line A-A′ of FIG. 3.

FIG. 4B is a sectional view taken along a line B-B′ of FIG. 3.

FIG. 5A is an enlarged sectional view illustrating a portion ‘N’ of FIG. 4A.

FIG. 5B is an enlarged sectional view illustrating a portion ‘M’ of FIG. 4B.

FIG. 6 is an enlarged sectional view illustrating the portion ‘M’ of FIG. 4B according to some implementations.

FIG. 7 is an enlarged sectional view illustrating the portion ‘M’ of FIG. 4B according to some implementations.

FIG. 8A is an enlarged sectional view illustrating the portion ‘N’ of FIG. 4A according to some implementations.

FIG. 8B is an enlarged sectional view illustrating the portion ‘M’ of FIG. 4B according to some implementations.

FIG. 9A is an enlarged sectional view illustrating the portion ‘N’ of FIG. 4A according to some implementations.

FIG. 9B is an enlarged sectional view illustrating the portion ‘M’ of FIG. 4B according to some implementations.

FIG. 10A is an enlarged sectional view illustrating the portion ‘N’ of FIG. 4A according to some implementations.

FIG. 10B is an enlarged sectional view illustrating the portion ‘M’ of FIG. 4B according to some implementations.

FIGS. 11A to 18A and FIGS. 11B to 18B are sectional views illustrating a method of fabricating an image sensor, according to some implementations and corresponding to the lines A-A′ and B-B′ of FIG. 4, respectively.

FIGS. 19A to 23A and FIGS. 19B to 23B are sectional views illustrating a method of fabricating an image sensor, according to some implementations and corresponding to the lines A-A′ and B-B′ of FIG. 4, respectively.

FIGS. 24A to 26A and FIGS. 24B to 26B are sectional views illustrating a method of fabricating an image sensor, according to some implementations and corresponding to the lines A-A′ and B-B′ of FIG. 4, respectively.

FIGS. 27A to 31A and FIGS. 27B to 31B are sectional views illustrating a method of fabricating an image sensor, according to some implementations and corresponding to the lines A-A′ and B-B′ of FIG. 4, respectively.

FIGS. 32A to 36A and FIGS. 32B to 36B are sectional views illustrating a method of fabricating an image sensor, according to some implementations and corresponding to the lines A-A′ and B-B′ of FIG. 4, respectively.

FIGS. 37A to 40A and FIGS. 37B to 40B are sectional views illustrating a method of fabricating an image sensor, according to some implementations and corresponding to the lines A-A′ and B-B′ of FIG. 4, respectively.

### DETAILED DESCRIPTION

Example implementations will now be described more fully with reference to the accompanying drawings.

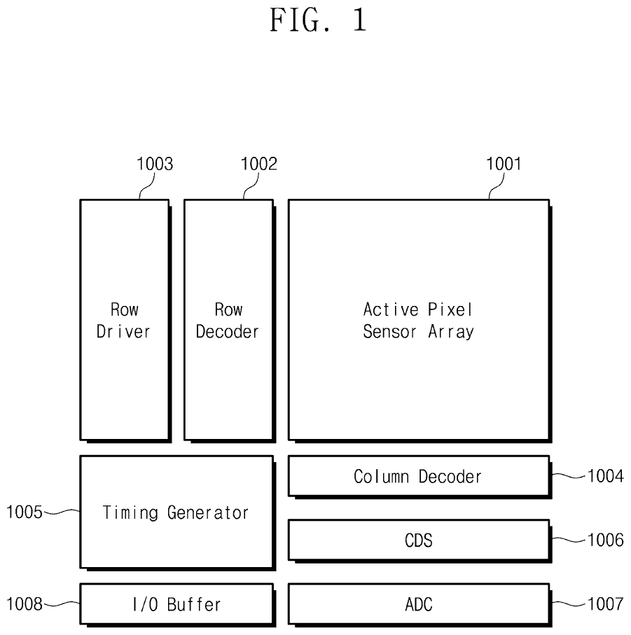

FIG. 1 is a block diagram schematically illustrating an image sensor according to some implementations.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels, which are two-dimensionally arranged and are used to convert an optical signal to an electrical signal. The active pixel sensor array 1001 may be driven by a plurality of driving signals, such as a pixel selection signal, a reset signal, and a charge transfer signal, which are transmitted from the row driver 1003. In addition, the converted electrical signal may be provided to the CDS 1006.

The row driver 1003 may be configured to provide a plurality of driving signals for driving the unit pixels to the active pixel sensor array 1001, based on the result decoded by the row decoder 1002. In the case where the unit pixels are arranged in a matrix shape (i.e., in rows and columns), the driving signals may be provided to respective rows.

The timing generator 1005 may be configured to provide a timing signal and a control signal to the row decoder 1002 and the column decoder 1004.

The CDS 1006 may be configured to receive the electric signals generated by the active pixel sensor array 1001 and to perform a holding and sampling operation on the received electric signals. The CDS 1006 may perform a double sampling operation using a specific noise level and a signal level of the electric signal and then may output a difference level corresponding to a difference between the noise and signal levels.

The ADC 1007 may be configured to convert an analog signal, which contains information on the difference level outputted from the CDS 1006, to a digital signal and to output the converted digital signal.

The I/O buffer 1008 may be configured to latch the digital signals and then to sequentially output the latched digital signals to an image signal processing unit (not shown), based on the result decoded by the column decoder 1004.

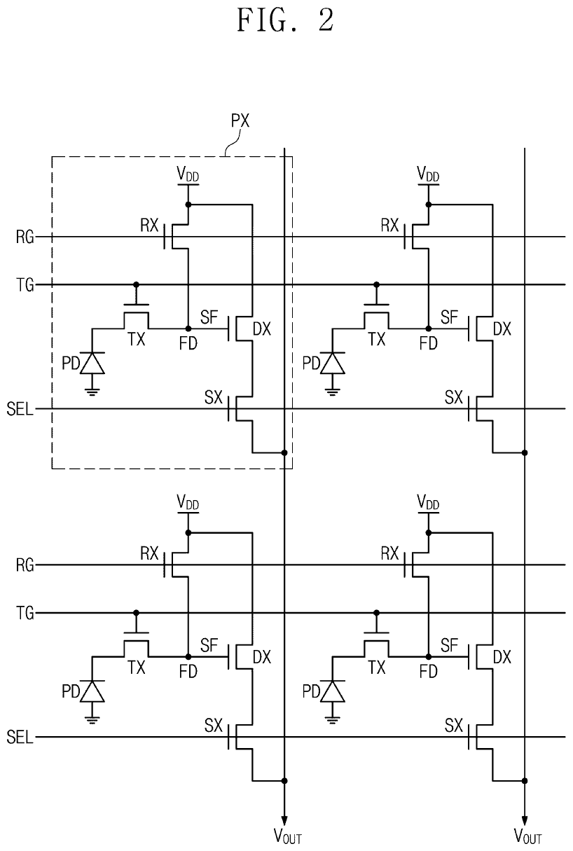

FIG. 2 is a circuit diagram illustrating an active pixel sensor array of an image sensor according to some implementations.

Referring to FIGS. 1 and 2, the active pixel sensor array 1001 may include a plurality of pixel regions PX, which are arranged in a matrix shape. Each pixel region PX may include a transfer transistor TX. Each pixel region PX may further include logic transistors RX, SX, and DX. The logic transistor may be a reset transistor RX, a selection transistor SX, or a source follower transistor DX. The transfer transistor TX may include a transfer gate TG. Each of the pixel regions PX may further include a photoelectric conversion part PD and a floating diffusion region FD. The logic transistors RX, SX, and DX may be shared by the pixel regions PX.

The photoelectric conversion part PD may be configured to generate photocharges whose amount is proportional to an amount of light incident from the outside and to store the photocharges. The photoelectric conversion part PD may include a photodiode, a photo transistor, a photogate, a pinned photodiode, or any combination thereof. The transfer transistor TX may be configured to transfer electric charges, which are generated in the photoelectric conversion part PD, to the floating diffusion region FD. The floating diffusion region FD may be configured to receive and cumulatively store the electric charges, which are generated in the photoelectric conversion part PD. The source follower transistor DX may be controlled, based on an amount of photocharges stored in the floating diffusion region FD.

The reset transistor RX may be configured to periodically discharge or reset the photocharges accumulated in the floating diffusion region FD. The reset transistor RX may include drain and source electrodes, which are connected to the floating diffusion region FD and a power voltage VDD, respectively. When the reset transistor RX is turned on, the power voltage VDD, which is connected to the source electrode of the reset transistor RX, may be applied to the floating diffusion region FD. Thus, if the reset transistor RX is turned on, the electric charges accumulated in the floating diffusion region FD may be discharged; that is, the floating diffusion region FD may be reset.

The source follower transistor DX including a source follower gate electrode SF may be used as a source follower buffer amplifier. The source follower transistor DX may be configured to amplify a variation in electric potential of the floating diffusion region FD and to output the amplified signal to an output line Vout.

The selection transistor SX including a selection gate electrode SEL may be used to select one of the rows of the pixel regions PX, during reading operations. When the selection transistor SX is turned on, the power voltage VDD may be applied to a drain electrode of the source follower transistor DX.

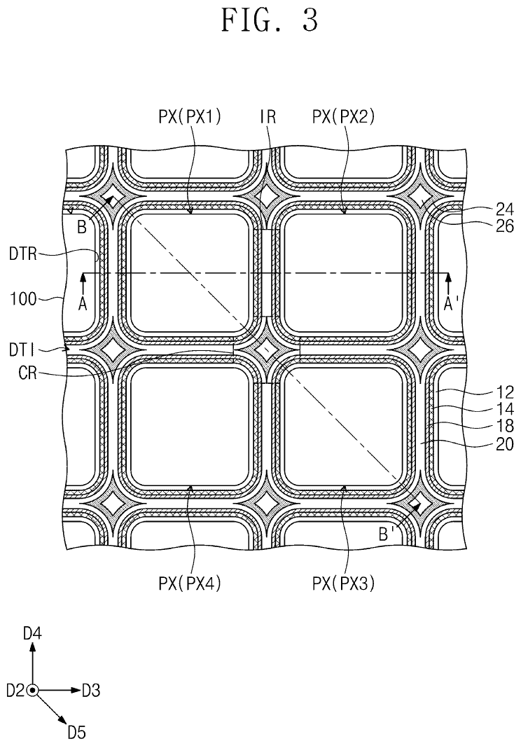

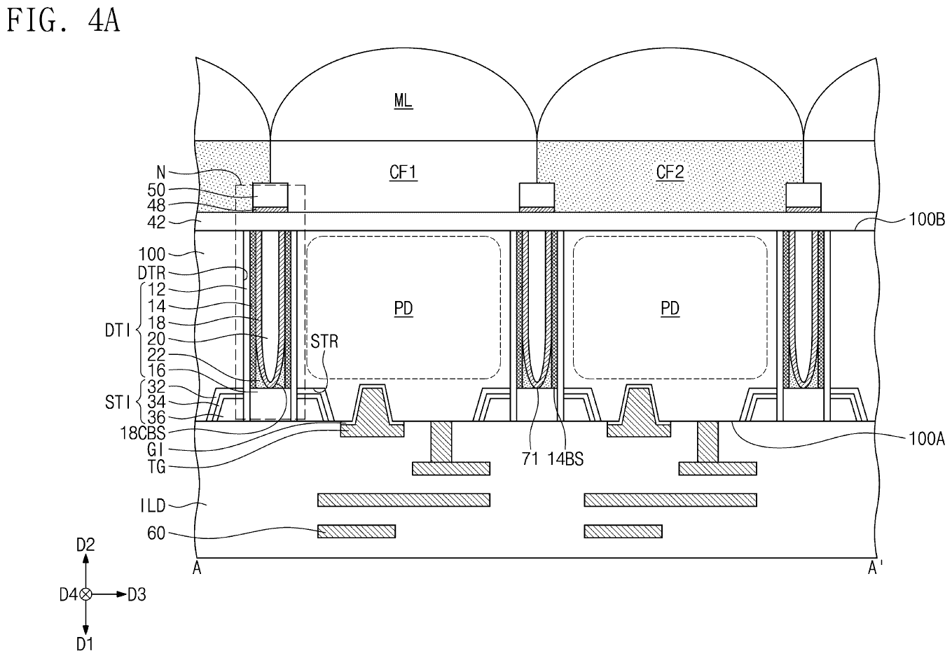

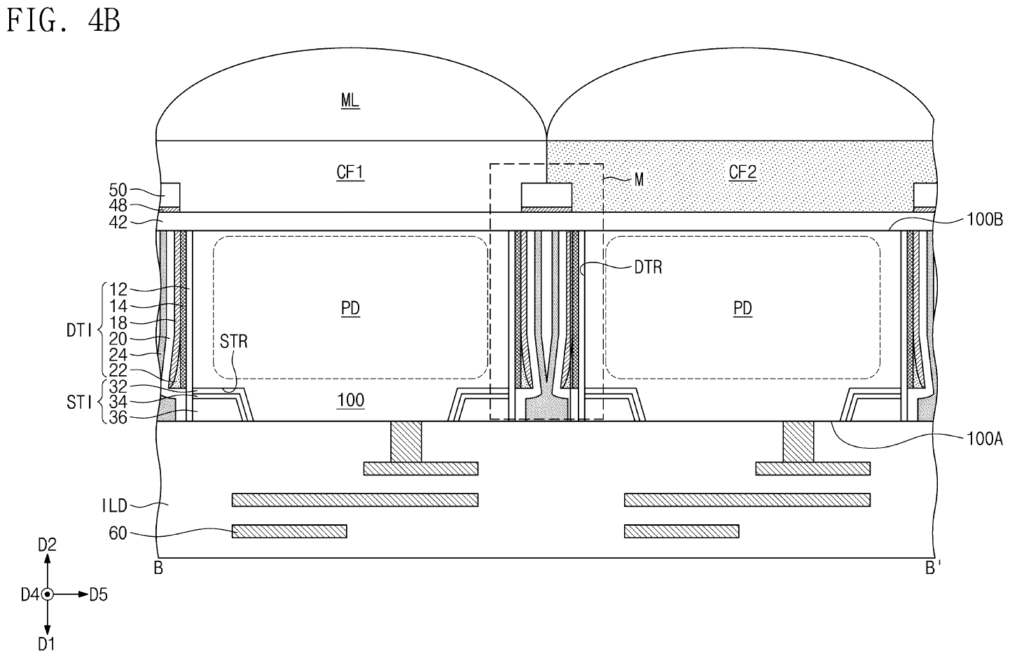

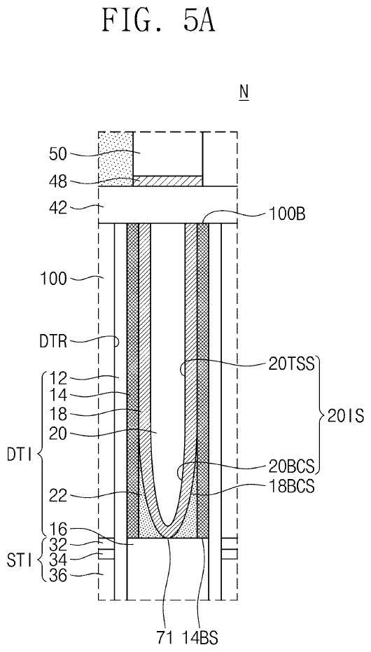

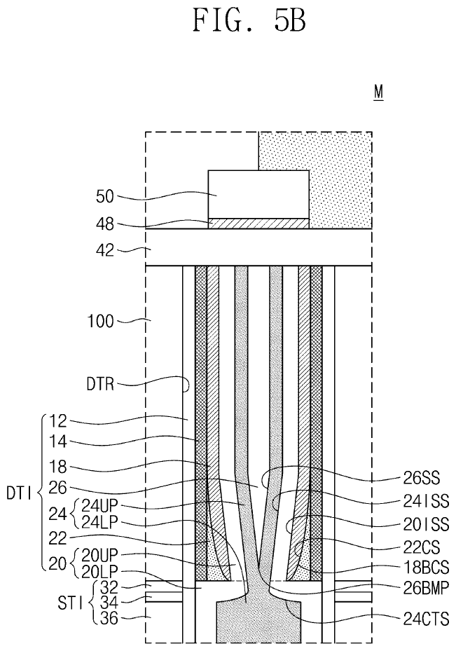

FIG. 3 is a plan view illustrating an image sensor according to some implementations. FIG. 4A is a sectional view taken along a line A-A′ of FIG. 3. FIG. 4B is a sectional view taken along a line B-B′ of FIG. 3. FIG. 5A is an enlarged sectional view illustrating a portion ‘N’ of FIG. 4A. FIG. 5B is an enlarged sectional view illustrating a portion ‘M’ of FIG. 4B.

Referring to FIGS. 3, 4A to 5A, and 4B to 5B, a substrate 100 may be provided. The substrate 100 may be, for example, a single-crystalline silicon wafer, a silicon epitaxial layer, or a silicon-on-insulator (SOI) substrate. In some implementations, the substrate 100 may be doped with impurities of a first conductivity type (e.g., p-type). The substrate 100 may include a first surface 100A and a second surface 100B, which are opposite to each other. An outward direction, which is normal to the first surface 100A, may be defined as a first direction D1, and an outward direction, which is normal to the second surface 100B, may be defined as a second direction D2. The first direction D1 and the second direction D2 may be opposite to each other.

The substrate 100 may include a plurality of the pixel regions PX. In some implementations, the substrate 100 may include first, second, third and fourth pixel regions PX1, PX2, PX3, and PX4, which are sequentially arranged in a clockwise direction when viewed in a plan view. The first and second pixel regions PX1 and PX2 may be arranged side by side in a third direction D3, and the third and fourth pixel regions PX3 and PX4 may also be arranged side by side in the third direction D3. The third direction D3 may be a direction parallel to the first surface 100A of the substrate 100. The second and third pixel regions PX2 and PX3 may be arranged side by side in a fourth direction D4, and the first and fourth pixel regions PX1 and PX4 may also be arranged side by side in the fourth direction D4. The fourth direction D4 may be a direction that is parallel to the first surface 100A of the substrate 100 and is not parallel to the third direction D3.

A device isolation pattern DTI may be provided in the substrate 100. The device isolation pattern DTI may be provided to separate the pixel regions PX from each other and delimit the pixel regions PX. The device isolation pattern DTI may penetrate the substrate 100 in the second direction D2, between the pixel regions PX.

The device isolation pattern DTI may be disposed in a device isolation trench DTR, which is extended from the first surface 100A toward the second surface 100B. When viewed in a plan view, the device isolation trench DTR may have a mesh shape, in which mesh lines are extended in the third and fourth directions D3 and D4.

The device isolation trench DTR may be extended from the first surface 100A into the substrate 100 and may be interposed between the pixel regions PX. The device isolation trench DTR may include an intervening region IR and an intersecting region CR.

The intervening region IR may be defined as a region between two adjacent ones of the pixel regions PX. The intersecting region CR may be defined as a region between four adjacent ones of the pixel regions PX. The intervening region IR and the intersecting region CR may be continuously connected to each other.

In the intervening region IR, the device isolation pattern DTI may include a gapfill insulating pattern 20, a conductive liner 18 in contact with the gapfill insulating pattern 20, an intervening insulating pattern 22 in contact with the conductive liner 18, a first insulating liner 12 in contact with the substrate 100, a second insulating liner 14 in contact with the intervening insulating pattern 22, and an underlying insulating layer 16 below the intervening insulating pattern 22.

In the intersecting region CR, the device isolation pattern DTI may include the first insulating liner 12 in contact with the substrate 100, the second insulating liner 14 on the first insulating liner 12, the conductive liner 18 in contact with the second insulating liner 14, the intervening insulating pattern 22 in contact with the conductive liner 18 and the second insulating liner 14, the gapfill insulating pattern 20 on the conductive liner 18, an inner insulating pattern 24 in contact with the gapfill insulating pattern 20, and a gap portion 26, which is defined at a center portion of the intersecting region CR.

The device isolation pattern DTI in the intervening region IR will be first described below.

In the intervening region IR, the gapfill insulating pattern 20 may be in contact with the second surface 100B of the substrate 100. The gapfill insulating pattern 20 may be extended from the second surface 100B of the substrate 100 in the first direction D1. A top surface of the gapfill insulating pattern 20 may be in contact with the second surface 100B of the substrate 100, and an inner surface 20IS of the gapfill insulating pattern 20 may be enclosed by the conductive liner 18.

The inner surface 20IS of the gapfill insulating pattern 20 may include a lower curved surface 20BCS and an upper flat surface 20TSS. The lower curved surface 20BCS and the upper flat surface 20TSS may be continuously connected to each other.

The gapfill insulating pattern 20 may include a filler. The gapfill insulating pattern 20 may include, for example, silicon oxide (SiO₂) or polysilicon.

In the intervening region IR, the conductive liner 18 may be provided to be in contact with the gapfill insulating pattern 20. The bottommost portion 71 of the conductive liner 18 may be in contact with the underlying insulating layer 16. A bottom surface 18BCS of the conductive liner 18 may include a curved surface. An interface between the conductive liner 18 and the intervening insulating pattern 22 may be defined as the bottom surface 18BCS of the conductive liner 18.

An outer side surface of the conductive liner 18 may be in contact with the second insulating liner 14 and the intervening insulating pattern 22. The interface between the conductive liner 18 and the intervening insulating pattern 22 may include a curved surface. The interface between the conductive liner 18 and the second insulating liner 14 may include a flat surface. In the intervening region IR, the conductive liner 18 may have a continuous structure.

The conductive liner 18 may include a conductive material (e.g., B-doped polysilicon), which contains a p-type impurity (e.g., B) or an n-type impurity (e.g., P) and has a concentration of 1.0E15-2.0E16/cm³, or a conductive metal.

In the intervening region IR, a distance from the second surface 100B of the substrate 100 to the bottommost surface of the gapfill insulating pattern 20 may be smaller than a distance from the second surface 100B of the substrate 100 to the bottommost portion 71 of the conductive liner 18.

In the intervening region IR, the first insulating liner 12 may be provided to be in contact with the substrate 100. An outer side surface of the first insulating liner 12 may be in contact with the substrate 100. The first insulating liner 12 may be provided to penetrate the substrate 100.

In the intervening region IR, the second insulating liner 14 may be provided to be in contact with the first insulating liner 12 and the intervening insulating pattern 22. The second insulating liner 14 may be in contact with the conductive liner 18. The second insulating liner 14 may be interposed between the first insulating liner 12 and the conductive liner 18 and between the first insulating liner 12 and the intervening insulating pattern 22. The bottom surface 18BCS of the conductive liner 18 may not be in contact with the second insulating liner 14.

A length of the second insulating liner 14 from the first surface 100A of the substrate 100 may be substantially equal to a distance from the bottommost point 71 of the conductive liner 18 to the first surface 100A of the substrate 100. Here, the expression “substantially equal to” may mean a margin of error that is smaller than 20%. In some implementations, a distance from a bottom surface 14BS of the second insulating liner 14 to the second surface 100B of the substrate 100 may be 80% to 120% of the distance from the bottommost point 71 of the conductive liner 18 to the second surface 100B of the substrate 100.

The first insulating liner 12 may include an oxide material. The second insulating liner 14 may include a nitride material. The first insulating liner 12 may include, for example, silicon oxide. The first insulating liner 12 may include, for example, silicon oxide (SiO₂). The second insulating liner 14 may include, for example, silicon nitride. The second insulating liner 14 may include, for example, Si₃N₄ (nitride), SiCN, SiOCN, SiBN, SiBCN, or SiON.

The first insulating liner 12 and the second insulating liner 14 may include different materials having different etching rates from each other or having an etch selectivity. For example, the first insulating liner 12 may be etched using an HF solution, and the second insulating liner 14 may resist being etched by the HF solution and may be etched by a phosphoric acid solution.

In the intervening region IR, the underlying insulating layer 16 may be provided below the intervening insulating pattern 22. A top surface of the underlying insulating layer 16 may be in contact with the intervening insulating pattern 22 and the second insulating liner 14. A side surface of the underlying insulating layer 16 may be in contact with the first insulating liner 12. The top surface of the underlying insulating layer 16 may be in contact with the bottommost portion 71 of the conductive liner 18. The underlying insulating layer 16 may include silicon oxide or silicon nitride. The underlying insulating layer 16 and the gapfill insulating pattern 20 may include the same material. The underlying insulating layer 16 may be provided to penetrate a shallow device isolation pattern STI, which will be described below.

Hereinafter, the device isolation pattern DTI in the intersecting region CR will be described.

In the intersecting region CR, the first insulating liner 12 in contact with the substrate 100 may be provided. The first insulating liner 12 may penetrate the substrate 100.

In the intersecting region CR, the second insulating liner 14 may be provided on the first insulating liner 12. The second insulating liner 14 may include a material different from the first insulating liner 12. The second insulating liner 14 may be extended from the first surface 100A of the substrate 100 in the second direction D2.

In the intersecting region CR, the conductive liner 18 in contact with the second insulating liner 14 may be provided. The conductive liner 18 may be in contact with the gapfill insulating pattern 20. An interface between the conductive liner 18 and the gapfill insulating pattern 20 may include a flat surface.

An interface between the conductive liner 18 and the intervening insulating pattern 22 may be defined as the bottom surface 18BCS of the conductive liner 18. The bottom surface 18BCS of the conductive liner 18 may include a curved surface. The conductive liner 18 in the intersecting region CR may be illustrated to be separated from each other, when viewed in a sectional view.

In the intersecting region CR, the intervening insulating pattern 22, which is in contact with the conductive liner 18 and the second insulating liner 14, may be provided. An interface between the intervening insulating pattern 22 and the conductive liner 18 may be defined as a top surface 22CS of the intervening insulating pattern 22. The top surface 22CS of the intervening insulating pattern 22 may include a curved surface. A side surface of the intervening insulating pattern 22 may be in contact with the second insulating liner 14, and a bottom surface of the intervening insulating pattern 22 may be in contact with the gapfill insulating pattern 20. The intervening insulating pattern 22 may be interposed between the conductive liner 18 and the second insulating liner 14.

In the intersecting region CR, the gapfill insulating pattern 20 may be provided on the conductive liner 18. The gapfill insulating pattern 20 may be in contact with the inner insulating pattern 24. The gapfill insulating pattern 20 may be in contact with the conductive liner 18. The gapfill insulating pattern 20 may be in contact with the first surface 100A of the substrate 100.

The gapfill insulating pattern 20 may include a lower gapfill insulating pattern 20LP, which is adjacent to the first surface 100A of the substrate 100, and an upper gapfill insulating pattern 20UP, which is provided on the lower gapfill insulating pattern 20LP. The lower gapfill insulating pattern 20LP and the upper gapfill insulating pattern 20UP may be continuously connected to each other. The lower gapfill insulating pattern 20LP may be defined as a portion of the gapfill insulating pattern 20, which is horizontally overlapped with a shallow device isolation pattern STI to be described below. The upper gapfill insulating pattern 20UP may be defined as that portion of the gapfill insulating pattern 20 which is horizontally overlapped with the second insulating liner 14.

The upper gapfill insulating pattern 20UP may have an inclined side surface 20ISS. An outer side surface of the upper gapfill insulating pattern 20UP may be in contact with the conductive liner 18. An inner side surface of the upper gapfill insulating pattern 20UP may be in contact with the inner insulating pattern 24.

The lower gapfill insulating pattern 20LP may be in contact with the first insulating liner 12, the second insulating liner 14, the intervening insulating pattern 22, and the inner insulating pattern 24. In some implementations, the lower gapfill insulating pattern 20LP may be in contact with the conductive liner 18. A surface 24CTS of the inner insulating pattern 24 in contact with the lower gapfill insulating pattern 20LP may include a curved surface. The interface between the lower gapfill insulating pattern 20LP and the inner insulating pattern 24 may also include a flat surface. The flat surface may be a portion of the interface between the lower gapfill insulating pattern 20LP and the inner insulating pattern 24, which is close to the first surface 100A of the substrate 100.

In the intersecting region CR, the inner insulating pattern 24 may be provided to be in contact with the gapfill insulating pattern 20. The inner insulating pattern 24 may include a lower inner insulating pattern 24LP, which is in contact with the first surface 100A of the substrate 100, and an upper inner insulating pattern 24UP, which is provided on the lower inner insulating pattern 24LP. The interface 24CTS between the lower inner insulating pattern 24LP and the gapfill insulating pattern 20 may include a curved surface. A sidewall of the upper inner insulating pattern 24UP may include an inclined surface 24ISS. A width of the upper inner insulating pattern 24UP may remain constant and then be reduced as a distance to the first surface 100A of the substrate 100 decreases.

The inner insulating pattern 24 may include an oxide filler. The inner insulating pattern 24 may include, for example, high density plasma (HDP) oxide, silicon oxide, or silicon nitride.

In the intersecting region CR, the device isolation pattern DTI may include the inner insulating pattern 24 and the gap portion 26, which is defined in the center portion of the intersecting region CR. The inner insulating pattern 24 may be provided to define the gap portion 26. The upper inner insulating pattern 24UP may include two portions, which are spaced apart from each other to define the gap portion 26, when viewed in a sectional view. An inner side surface of the inner insulating pattern 24UP defining the gap portion 26 may be referred to as a gap side surface 26SS. The gap side surface 26SS may include an inclined surface. The bottommost point 26BMP of the gap portion 26 may be located farther from the first surface 100A of the substrate 100 than the bottommost surface of the second insulating liner 14.

In some implementations, the gap portion 26 may be an air gap. The gap portion 26 may be an empty space. In some implementations, the gap portion 26 may include the same material as an anti-reflection layer 42, which will be described below. A width of the gap portion 26 may remain constant and then be reduced as a distance from the second surface 100B of the substrate 100 increases.

Referring back to FIGS. 4A and 4B, the photoelectric conversion part PD may be provided in each of the pixel regions PX. The photoelectric conversion part PD may be doped with impurities to have a second conductivity type (e.g., n-type) different from the first conductivity type. The photoelectric conversion part PD and the substrate 100, which have different conductivity types from each other, may form a PN junction, which is used as a photodiode.

A shallow device isolation trench STR, which is recessed from the first surface 100A of the substrate 100 into the substrate 100, may be provided, and a shallow device isolation pattern STI may be provided to fill the shallow device isolation trench STR. The shallow device isolation pattern STI may be disposed to be adjacent to the first surface 100A of the substrate 100.

In some implementations, the shallow device isolation pattern STI may include a first isolation portion 32, a second isolation portion 34, and a third isolation portion 36. The first isolation portion 32 and the second isolation portion 34 may conformally cover an inner surface of the shallow device isolation trench STR. The third isolation portion 36 may fill an inner space of the shallow device isolation trench STR. The second isolation portion 34 may be provided on the third isolation portion 36, and the first isolation portion 32 may be provided on the second isolation portion 34. The first isolation portion 32 may include an oxide material, and the second isolation portion 34 may include a nitride material. The first isolation portion 32 may include silicon oxide (SiO). The second isolation portion 34 may include silicon nitride (SiN) or silicon carbon nitride (SiCN).

The device isolation pattern DTI may be provided to penetrate the shallow device isolation pattern STI in the second direction D2. In the pixel region PX, the shallow device isolation pattern STI may delimit active regions, which are adjacent to the second surface 100B of the substrate 100. The active regions may be provided for the transistors TX, RX, DX, and SX of FIG. 2.

The underlying insulating layer 16 may be provided to penetrate the shallow device isolation pattern STI. The first insulating liner 12 may be interposed between the underlying insulating layer 16 and the shallow device isolation pattern STI.

In each pixel region PX, the transfer gate TG may be provided on the first surface 100A of the substrate 100. In some implementations, a portion of the transfer gate TG may be buried in the substrate 100. The transfer gate TG may be of a vertical type. In some implementations, the transfer gate TG may be a planar or flat-shaped pattern, which is provided on the first surface 100A of the substrate 100.

A gate insulating pattern GI may be interposed between the transfer gate TG and the substrate 100. A floating diffusion region may be provided in a portion of the substrate 100 adjacent to a side of the transfer gate TG. In some implementations, the floating diffusion region may be doped with impurities of the second conductivity type.

In some implementations, light may be incident into the substrate 100 through the second surface 100B of the substrate 100. Electron-hole pairs may be generated in the PN junction by the incident light. The electrons, which are generated by this process, may be transferred to the photoelectric conversion part PD. The electrons may be transferred to the floating diffusion region by applying a voltage to the transfer gate TG.

An interlayer insulating layer ILD may be provided on the first surface 100A of the substrate 100 to cover the first surface 100A. The interlayer insulating layer ILD may be a composite layer including at least one of silicon oxide, silicon nitride, silicon oxynitride, or porous low-k dielectric materials. Interconnection lines 60 may be provided in the interlayer insulating layer ILD. The floating diffusion region may be connected to the interconnection lines 60.

An anti-reflection layer 42 may be provided on the second surface 100B of the substrate 100 to cover the second surface 100B. In some implementations, the anti-reflection layer 42 may be a metal oxide layer whose oxygen content is lower than its stoichiometric ratio, a metal fluoride layer whose fluorine content ratio is lower than its stoichiometric ratio, or a single or multi-layered structure including at least one of them. Thus, the anti-reflection layer 42 may have negative fixed charges. As an example, the anti-reflection layer 42 may include a metal oxide layer or a metal fluoride layer, which contains at least one of hafnium (Hf), zirconium (Zr), aluminum (Al), tantalum (Ta), titanium (Ti), yttrium (Y), or lanthanum (La). The anti-reflection layer 42 may contribute to improve a dark current issue and a white spot issue.

Light-blocking patterns 48 may be disposed on the anti-reflection layer 42. Low refractive patterns 50 may be disposed on the light-blocking patterns 48, respectively. The light-blocking pattern 48 and the low refractive pattern 50 may have a grid shape, when viewed in a plan view. The light-blocking pattern 48 may include, for example, titanium. The low refractive patterns 50 may have the same thickness and may include the same organic material. The low refractive pattern 50 may have a refractive index that is smaller than color filters CF1 and CF2 to be described below. The light-blocking pattern 48 and the low refractive pattern 50 may prevent a cross-talk issue from occurring between adjacent ones of the pixel regions PX.

Color filters CF1 and CF2 may be disposed between the low refractive patterns 50. Each of the color filters CF1 and CF2 may have one of blue, green, and red colors. In some implementations, the color filters CF1 and CF2 may be provided to have other colors, such as cyan, magenta, or yellow. In the image sensor according to the present some implementations, the color filters CF1 and CF2 may be arranged in the form of a Bayer pattern. Alternatively, the color filters CF1 and CF2 may be arranged in the form of a 2×2 tetra pattern, a 3×3 nona pattern, or a 4×4 hexadeca pattern.

Micro lenses ML may be disposed on the color filters CF1 and CF2. The micro lenses ML may have edge portions that are in contact with each other and are connected to each other.

The image sensor may include the gap portion 26 and may include the conductive liner 18. Since the image sensor includes the gap portion 26, it may be possible to reduce an amount of a material having a relatively-high optical absorptivity, and thus, the sensitivity of the image sensor may be increased. Since the image sensor includes the conductive liner 18, it may be possible to reduce a yield loss, which is caused by a pattern shifting or leaning issue and a field empty issue in the fabrication process.

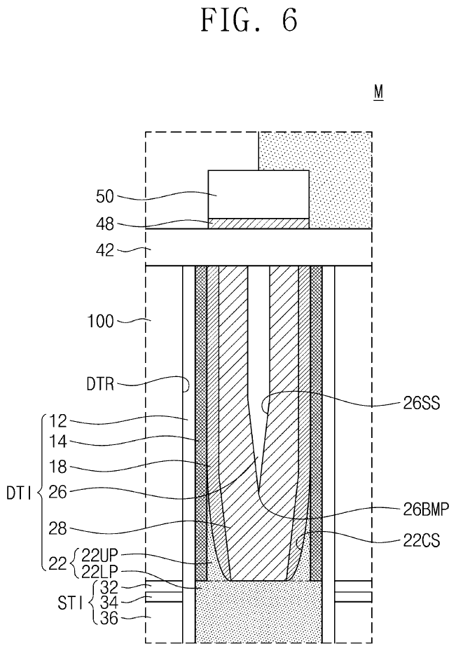

FIG. 6 is an enlarged sectional view illustrating the portion ‘M’ of FIG. 4B according to some implementations. For concise description, a previously described element may be identified by the same reference number without repeating an overlapping description thereof.

Referring to FIG. 6, the device isolation pattern DTI in the intersecting region CR may include the first insulating liner 12 in contact with the substrate 100, the second insulating liner 14 on the first insulating liner 12, the conductive liner 18 in contact with the second insulating liner 14, the intervening insulating pattern 22 in contact with the conductive liner 18 and the second insulating liner 14, a gapfill layer 28 on the conductive liner 18, and the gap portion 26, which is defined in the gapfill layer 28 and at the center portion of the intersecting region CR.

The gapfill layer 28 may be provided between the conductive liner 18 and the gap portion 26. The conductive liner 18 may include portions that are spaced apart from each other by the gapfill layer 28. The gapfill layer 28 may include a conductive material. The gapfill layer 28 may include, for example, poly silicon. The gapfill layer 28 may be provided on the conductive liner 18. An inner side surface of the gapfill layer 28 defining the gap portion 26 may be referred to as the gap side surface 26SS. The gap side surface 26SS may be inclined at an angle.

The intervening insulating pattern 22 may be provided between the conductive liner 18 and the second insulating liner 14 and on the first surface 100A of the substrate 100. The intervening insulating pattern 22 may include a lower intervening insulating pattern 22LP in contact with the first surface 100A and an upper intervening insulating pattern 22UP protruding from the lower intervening insulating pattern 22LP.

The upper intervening insulating pattern 22UP may be interposed between the conductive liner 18 and the second insulating liner 14. A surface of the upper intervening insulating pattern 22UP, which is in contact with the conductive liner 18, may be defined as a top surface 22CS of the intervening insulating pattern 22. The top surface 22CS of the intervening insulating pattern 22 may include a curved surface.

The bottommost point 26BMP of the gap portion 26 may be disposed in the gapfill layer 28. A distance between the bottommost point 26BMP of the gap portion 26 and the first surface 100A of the substrate 100 may be larger than a distance between the bottommost surface of the second insulating liner 14 and the first surface 100A of the substrate 100.

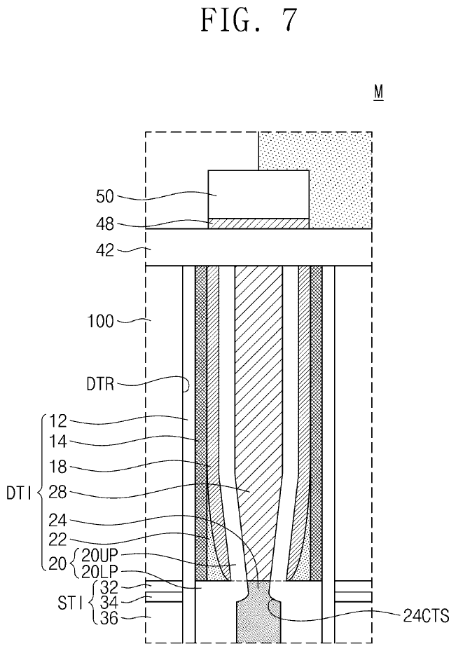

FIG. 7 is an enlarged sectional view illustrating the portion ‘M’ of FIG. 4B according to some implementations. For concise description, a previously described element may be identified by the same reference number without repeating an overlapping description thereof.

Referring to FIG. 7, in the intersecting region CR, the device isolation pattern DTI may include the first insulating liner 12 in contact with the substrate 100, the second insulating liner 14 on the first insulating liner 12, the conductive liner 18 in contact with the second insulating liner 14, the intervening insulating pattern 22 in contact with the conductive liner 18 and the second insulating liner 14, the gapfill insulating pattern 20 on the conductive liner 18, and the gapfill layer 28 on the gapfill insulating pattern 20. A gap portion may be defined in a center portion of the gapfill layer 28, similar to the device isolation pattern DTI of FIG. 6.

The gapfill insulating pattern 20 may include the lower gapfill insulating pattern 20LP in contact with the first surface 100A of the substrate 100 and the upper gapfill insulating pattern 20UP on the lower gapfill insulating pattern 20LP. The lower gapfill insulating pattern 20LP and the upper gapfill insulating pattern 20UP may be continuously connected to each other. The lower gapfill insulating pattern 20LP may be defined as a portion of the gapfill insulating pattern 20, which is horizontally overlapped with a shallow device isolation pattern STI to be described below. The upper gapfill insulating pattern 20UP may be defined as that portion of the gapfill insulating pattern 20 which is horizontally overlapped with the second insulating liner 14.

An outer side surface of the upper gapfill insulating pattern 20UP may be in contact with the conductive liner 18. An inner side surface of the upper gapfill insulating pattern 20UP may be in contact with the gapfill layer 28.

The lower gapfill insulating pattern 20LP may be in contact with the first insulating liner 12, the second insulating liner 14, the intervening insulating pattern 22, and the inner insulating pattern 24. In some implementations, the lower gapfill insulating pattern 20LP may be in contact with the conductive liner 18. The surface 24CTS of the inner insulating pattern 24 in contact with the lower gapfill insulating pattern 20 may include a curved surface. The interface between the lower gapfill insulating pattern 20 and the inner insulating pattern 24 may also include a flat surface. The flat surface may be a portion of the interface between the lower gapfill insulating pattern 20 and the inner insulating pattern 24, which is close to the first surface 100A of the substrate 100.

In the intersecting region CR, the inner insulating pattern 24 may be provided to be in contact with the gapfill insulating pattern 20. The inner insulating pattern 24 may be in contact with the first surface 100A of the substrate 100. The inner insulating pattern 24 may be surrounded by the lower gapfill insulating pattern 20LP. A width of the inner insulating pattern 24 may remain constant and then be reduced as a distance to the first surface 100A of the substrate 100 decreases.

The gapfill layer 28 may be provided on the inner insulating pattern 24. The gapfill layer 28 may include a conductive material. A side surface of the gapfill layer 28 may be in contact with the gapfill insulating pattern 20.

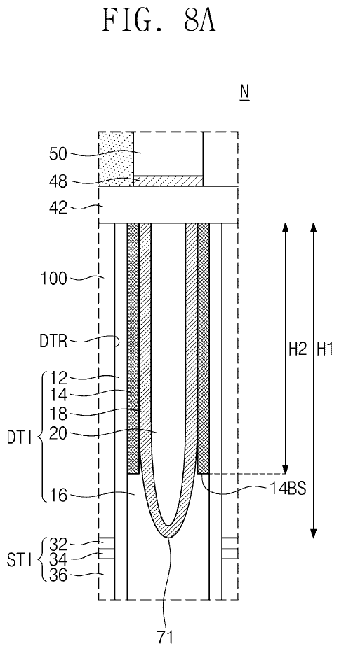

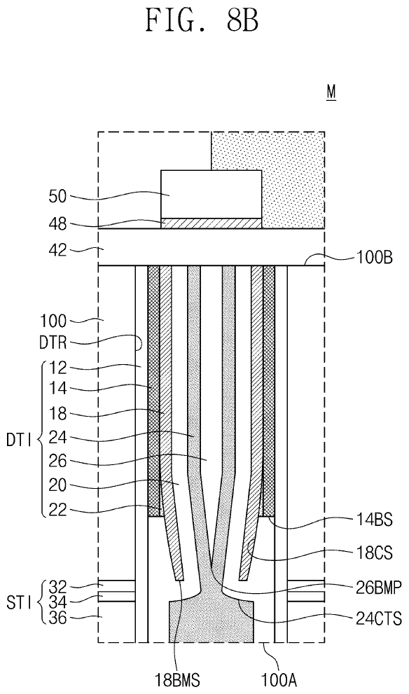

FIG. 8A is an enlarged sectional view illustrating the portion ‘N’ of FIG. 4A according to some implementations. FIG. 8B is an enlarged sectional view illustrating the portion ‘M’ of FIG. 4B according to some implementations. For concise description, a previously described element may be identified by the same reference number without repeating an overlapping description thereof.

Referring to FIGS. 8A and 8B, in the intervening region IR, the device isolation pattern DTI may include the first insulating liner 12 in contact with the substrate 100, the second insulating liner 14 in contact with the first insulating liner 12, the conductive liner 18 in contact with the second insulating liner 14, the gapfill insulating pattern 20 in contact with the conductive liner 18, and the underlying insulating layer 16 in contact with the conductive liner 18 and the second insulating liner 14.

In the intervening region IR, an interface between the underlying insulating layer 16 and the conductive liner 18 may include a curved surface. An outer side surface of the underlying insulating layer 16 may be in contact with the first insulating liner 12, a flat portion of the top surface of the underlying insulating layer 16 may be in contact with the second insulating liner 14, and a curved portion of the top surface of the underlying insulating layer 16 may be in contact with the conductive liner 18.

The conductive liner 18 may surround the gapfill insulating pattern 20. The gapfill insulating pattern 20 and the underlying insulating layer 16 may include the same material.

A distance H2 from the second surface 100B of the substrate 100 to the bottommost surface 14BS of the second insulating liner 14 may be smaller than a distance H1 from the second surface 100B of the substrate 100 to the bottommost point 71 of the conductive liner 18.

The distance H2 from the second surface 100B of the substrate 100 to the bottommost surface 14BS of the second insulating liner 14 may be 10% to 75% of the distance H1 from the second surface 100B of the substrate 100 to the bottommost point 71 of the conductive liner 18.

In the intersecting region CR, the device isolation pattern DTI may include the first insulating liner 12 in contact with the substrate 100, the second insulating liner 14 in contact with the first insulating liner 12, the conductive liner 18 in contact with the second insulating liner 14, the intervening insulating pattern 22 interposed between the conductive liner 18 and the second insulating liner 14, the gapfill insulating pattern 20 in contact with the intervening insulating pattern 22 and the conductive liner 18, the inner insulating pattern 24 in contact with the gapfill insulating pattern 20, and the gap portion 26 defined in the inner insulating pattern 24.

A distance between the bottommost surface 14BS of the second insulating liner 14 and the first surface 100A of the substrate 100 may be larger than a distance between the bottommost surface 18BMS of the conductive liner 18 and the first surface 100A of the substrate 100. A distance between the bottommost point 26BMP of the gap portion 26 and the first surface 100A of the substrate 100 may be greater than the distance between the bottommost surface 18BMS of the conductive liner 18 and the first surface 100A of the substrate 100. The distance between the bottommost point 26BMP of the gap portion 26 and the first surface 100A of the substrate 100 may be smaller than a distance between the bottommost surface 14BS of the second insulating liner 14 and the first surface 100A of the substrate 100.

The conductive liner 18 may be inserted into the gapfill insulating pattern 20. The conductive liner 18 may be provided to include a portion that is extended into the gapfill insulating pattern 20. A side surface 18CS of the conductive liner 18, which is in contact with the gapfill insulating pattern 20, may be a curved surface. A surface 24CTS of the inner insulating pattern 24 in contact with the gapfill insulating pattern 20 may be a curved surface.

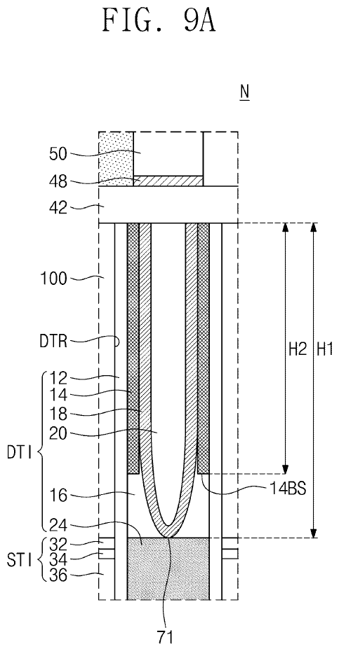

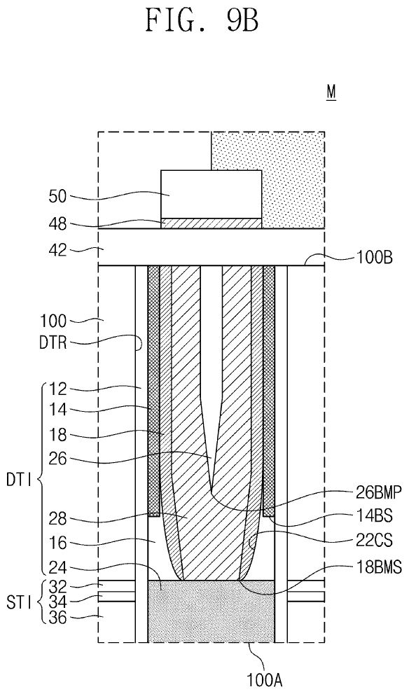

FIG. 9A is an enlarged sectional view illustrating the portion ‘N’ of FIG. 4A according to some implementations. FIG. 9B is an enlarged sectional view illustrating the portion ‘M’ of FIG. 4B according to some implementations. For concise description, a previously described element may be identified by the same reference number without repeating an overlapping description thereof.

Referring to FIGS. 9A and 9B, in the intervening region IR, the device isolation pattern DTI may include the first insulating liner 12 in contact with the substrate 100, the second insulating liner 14 in contact with the first insulating liner 12, the conductive liner 18 in contact with the second insulating liner 14, the gapfill insulating pattern 20 enclosed by the conductive liner 18, the underlying insulating layer 16 in contact with the conductive liner 18, and the inner insulating pattern 24 below the underlying insulating layer 16.

The distance H2 from the second surface 100B of the substrate 100 to the bottommost surface 14BS of the second insulating liner 14 may be smaller than the distance H1 from the second surface 100B of the substrate 100 to the bottommost point 71 of the conductive liner 18.

The distance H2 from the second surface 100B of the substrate 100 to the bottommost surface 14BS of the second insulating liner 14 may be 10% to 75% of the distance H1 from the second surface 100B of the substrate 100 to the bottommost point 71 of the conductive liner 18.

An outer side surface of the conductive liner 18 may be surrounded by the underlying insulating layer 16. A bottom surface of the underlying insulating layer 16 may be in contact with the inner insulating pattern 24. The top surface of the underlying insulating layer 16 may be in contact with the second insulating liner 14.

In the intersecting region CR, the device isolation pattern DTI may include the first insulating liner 12 in contact with the substrate 100, the second insulating liner 14 in contact with the first insulating liner 12, the conductive liner 18 in contact with the second insulating liner 14, the underlying insulating layer 16 in contact with the conductive liner 18, the inner insulating pattern 24 below the underlying insulating layer 16, the gapfill layer 28 on the conductive liner 18, and the gap portion 26 defined in the gapfill layer 28.

The underlying insulating layer 16 may be interposed between the second insulating liner 14 and the conductive liner 18. The underlying insulating layer 16 may be in contact with the first insulating liner 12, the second insulating liner 14, the conductive liner 18, and the inner insulating pattern 24.

A distance between the bottommost surface 14BS of the second insulating liner 14 and the first surface 100A of the substrate 100 may be larger than a distance between the bottommost surface 18BMS of the conductive liner 18 and the first surface 100A of the substrate 100. A distance between the bottommost point 26BMP of the gap portion 26 and the first surface 100A of the substrate 100 may be larger than a distance between the bottommost surface 18BMS of the conductive liner 18 and the first surface 100A of the substrate 100. A distance between the bottommost point 26BMP of the gap portion 26 and the first surface 100A of the substrate 100 may be larger than a distance between the bottommost surface 14BS of the second insulating liner 14 and the first surface 100A of the substrate 100.

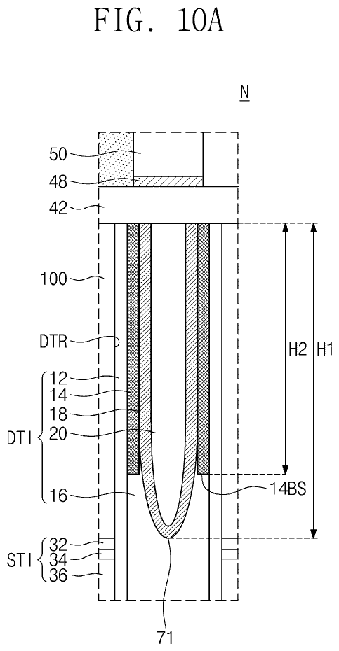

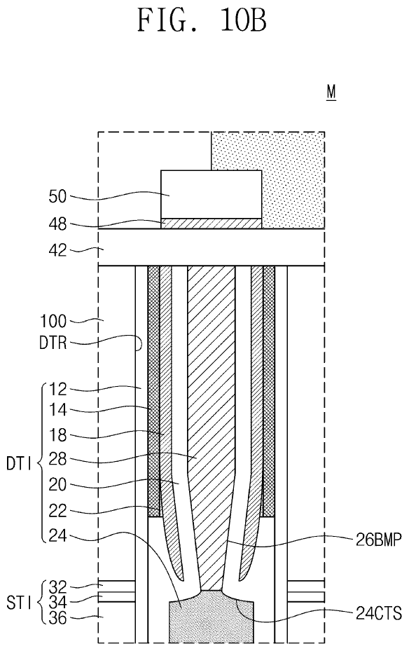

FIG. 10A is an enlarged sectional view illustrating the portion ‘N’ of FIG. 4A according to some implementations. FIG. 10B is an enlarged sectional view illustrating the portion ‘M’ of FIG. 4B according to some implementations. For concise description, a previously described element may be identified by the same reference number without repeating an overlapping description thereof.

Referring to FIGS. 10A and 10B, in the intervening region IR, the device isolation pattern DTI may include the first insulating liner 12 in contact with the substrate 100, the second insulating liner 14 in contact with the first insulating liner 12, the conductive liner 18 in contact with the second insulating liner 14, the gapfill insulating pattern 20 in contact with the conductive liner 18, the underlying insulating layer 16 in contact with the conductive liner 18 and the second insulating liner 14, and the inner insulating pattern 24 below the underlying insulating layer 16. A top surface of the inner insulating pattern 24 may be in contact with the underlying insulating layer 16.

In the intersecting region CR, the device isolation pattern DTI may include the first insulating liner 12 in contact with the substrate 100, the second insulating liner 14 in contact with the first insulating liner 12, the conductive liner 18 in contact with the second insulating liner 14, the gapfill insulating pattern 20 in contact with the conductive liner 18 and the second insulating liner 14, the gapfill layer 28 in contact with the gapfill insulating pattern 20, and the inner insulating pattern 24 below the gapfill layer 28. The gapfill layer 28 may be formed to have no empty space therein. The top surface 24CTS of the inner insulating pattern 24 in contact with the gapfill insulating pattern 20 may include a curved surface.

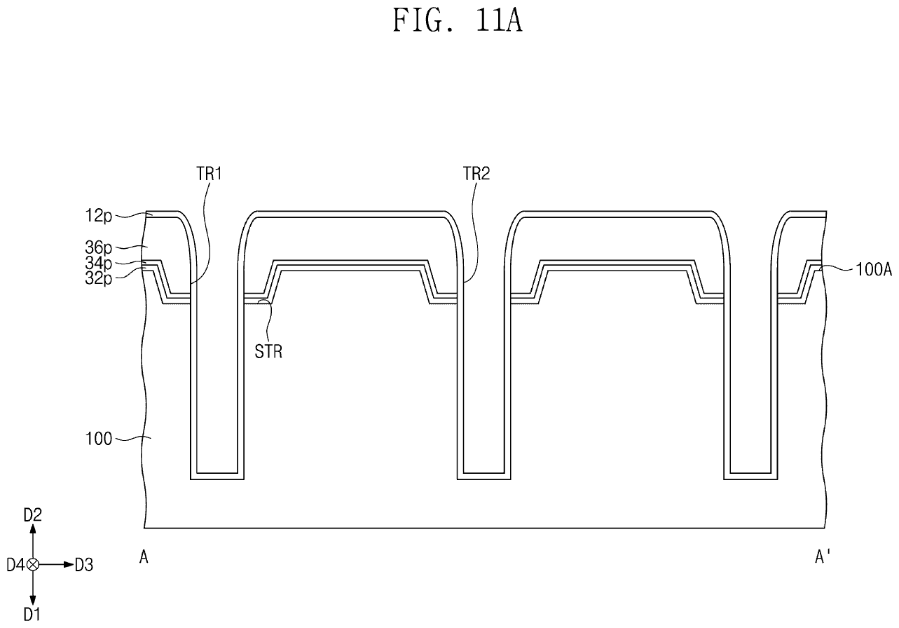

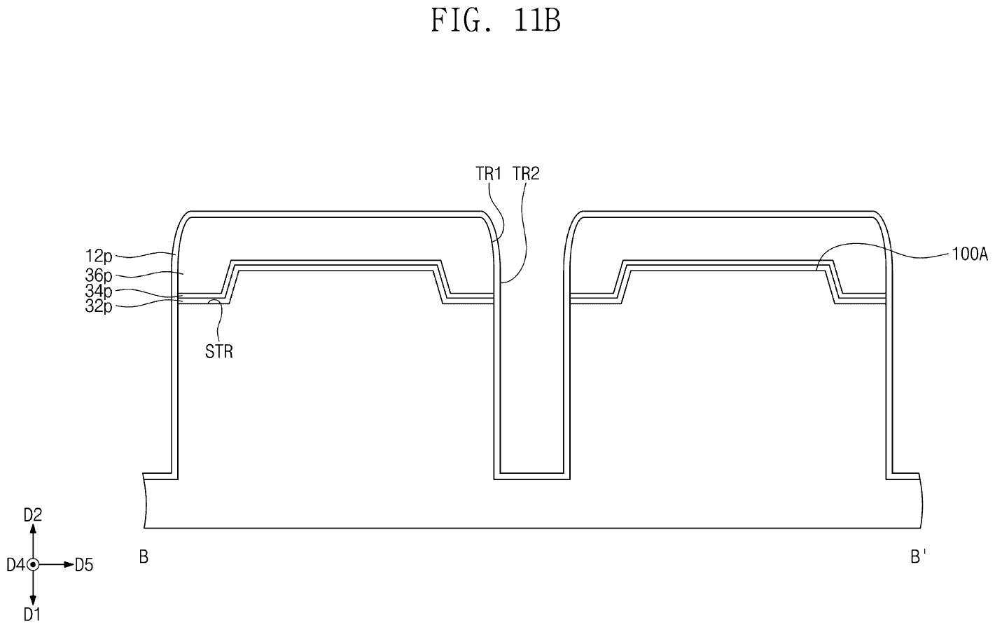

FIGS. 11A to 18A and FIGS. 11B to 18B are sectional views illustrating a method of fabricating an image sensor, according to some implementations and corresponding to the lines A-A′ and B-B′ of FIG. 4, respectively.

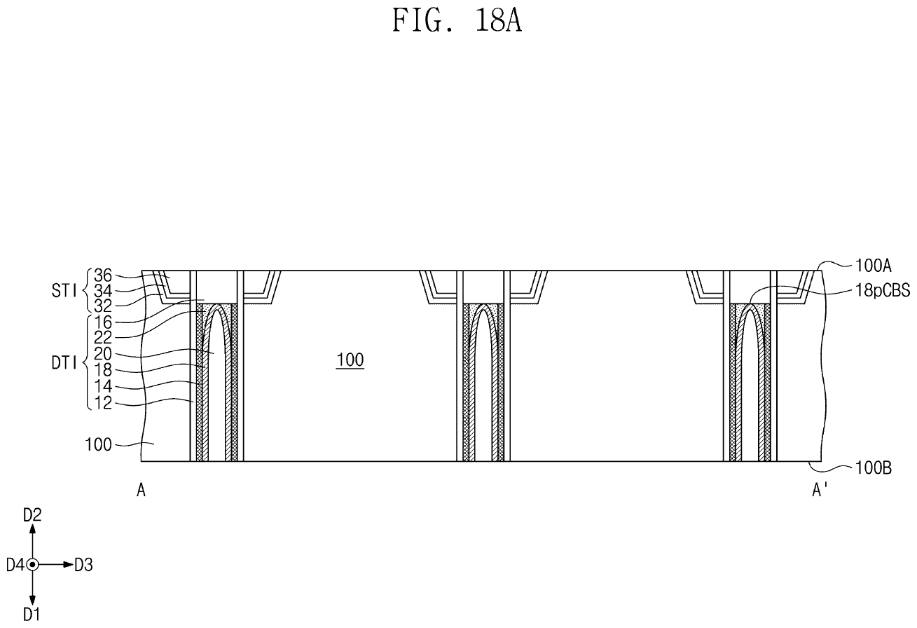

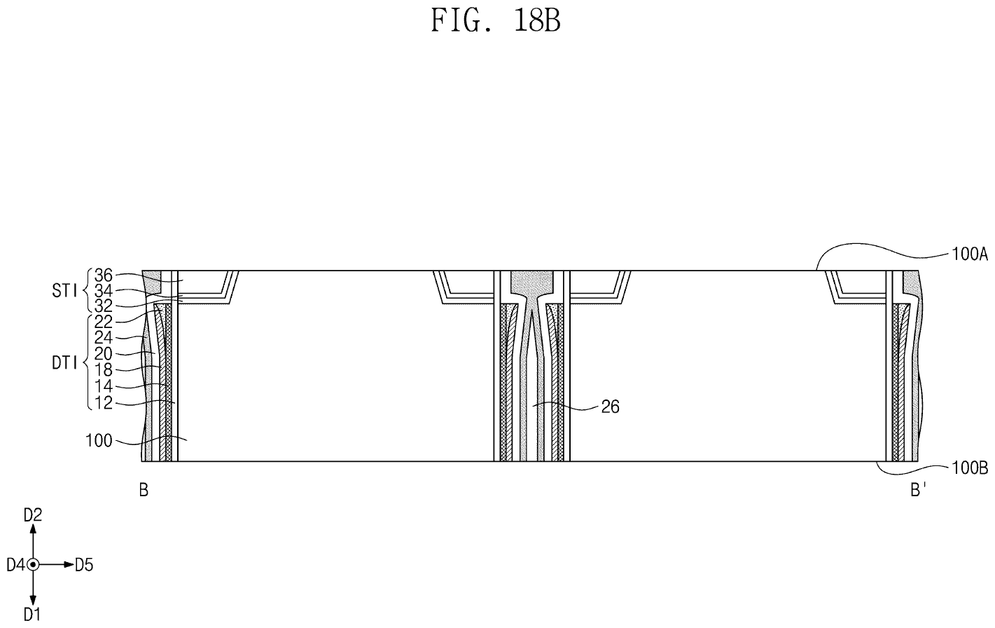

Referring to FIGS. 11A and 18B, the substrate 100 may be prepared. The shallow device isolation trench STR, which is recessed from the first surface 100A of the substrate 100 into the substrate 100, may be formed. The formation of the shallow device isolation trench STR may include forming a mask pattern on the first surface 100A of the substrate 100 and etching the substrate 100 using the mask pattern as an etch mask. The mask pattern may be partially left or fully removed, after the etching step.

A first isolation layer 32p may be formed to cover an inner surface of the shallow device isolation trench STR and the first surface 100A of the substrate 100. The first isolation layer 32p may include a portion of the mask pattern that is left after the etching step to form the shallow device isolation trench STR. A second isolation layer 34p may be formed on the first isolation layer 32p. A third isolation layer 36p may be formed to fill a remaining portion of the shallow device isolation trench STR and to cover the first surface 100A of the substrate 100.

A first trench TR1 may be formed to penetrate the first isolation layer 32p, the second isolation layer 34p, the third isolation layer 36p, and a portion of the substrate 100. When viewed in a plan view, the first trench TR1 may have a mesh shape, in which mesh lines are extended in the third and fourth directions D3 and D4. An inner portion of the substrate 100 may be exposed through the first trench TR1. The first trench TR1 may delimit the position and shape of the pixel region PX. A width of the first trench TR1 in the intervening region IR may be smaller than a width of the first trench TR1 in the intersecting region CR.

A doped region may be formed along an inner surface of the first trench TR1. In some implementations, the doped region may be formed by performing a boron doping process on the inner surface of the first trench TR1.

A first insulating liner layer 12p may be formed on the first surface 100A of the substrate 100. The first insulating liner layer 12p may conformally cover the inner surface of the first trench TR1. The first insulating liner layer 12p may fill a portion of the first trench TR1. The first insulating liner layer 12p may include silicon oxide (SiO). The first insulating liner layer 12p may be a single layer, which is made of a single material, or a composite layer including two or more materials. The first insulating liner layer 12p may conformally cover the inner surface of the first trench TR1, and as a result, a second trench TR2 may be formed.

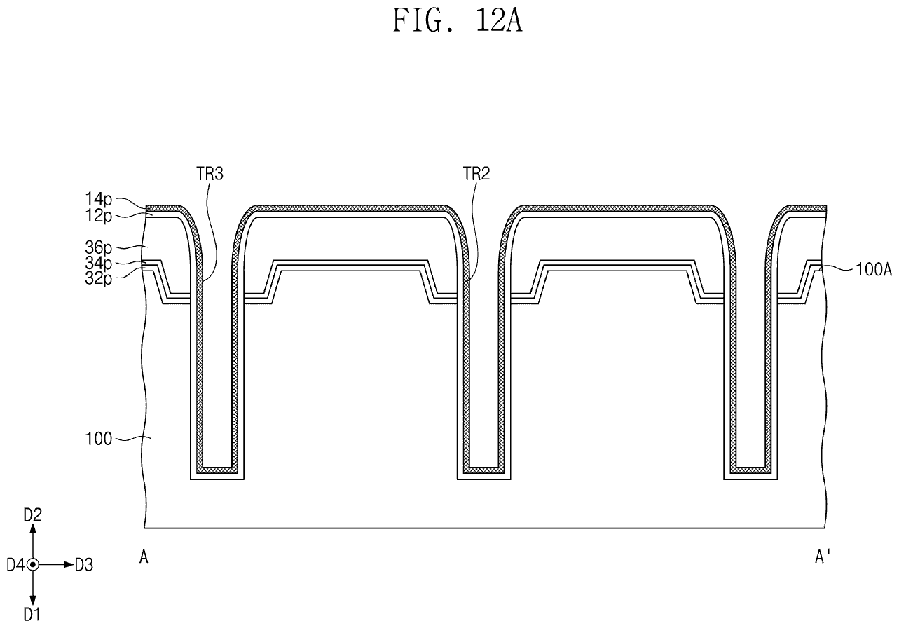

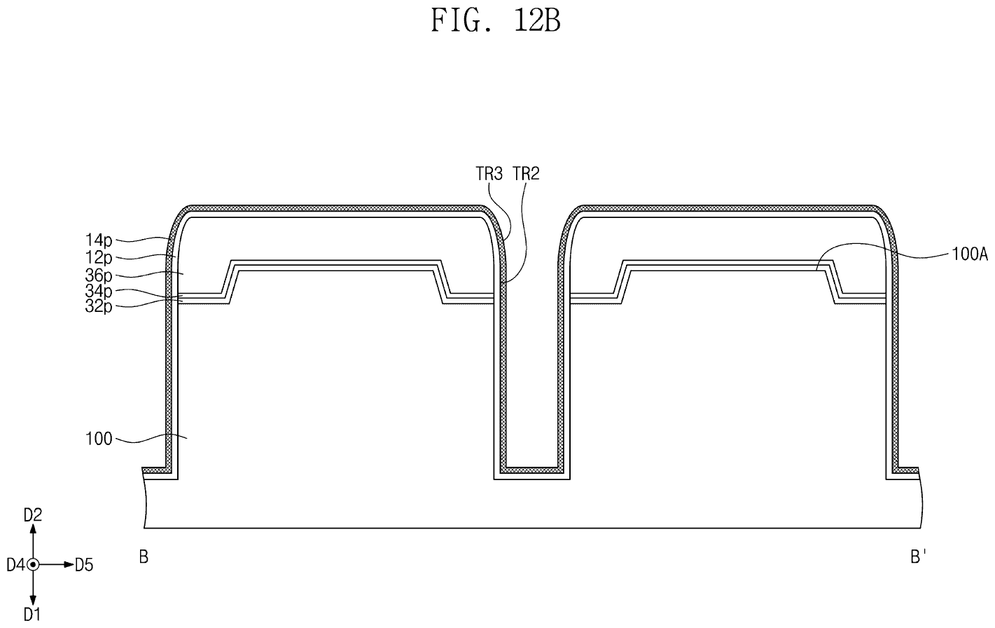

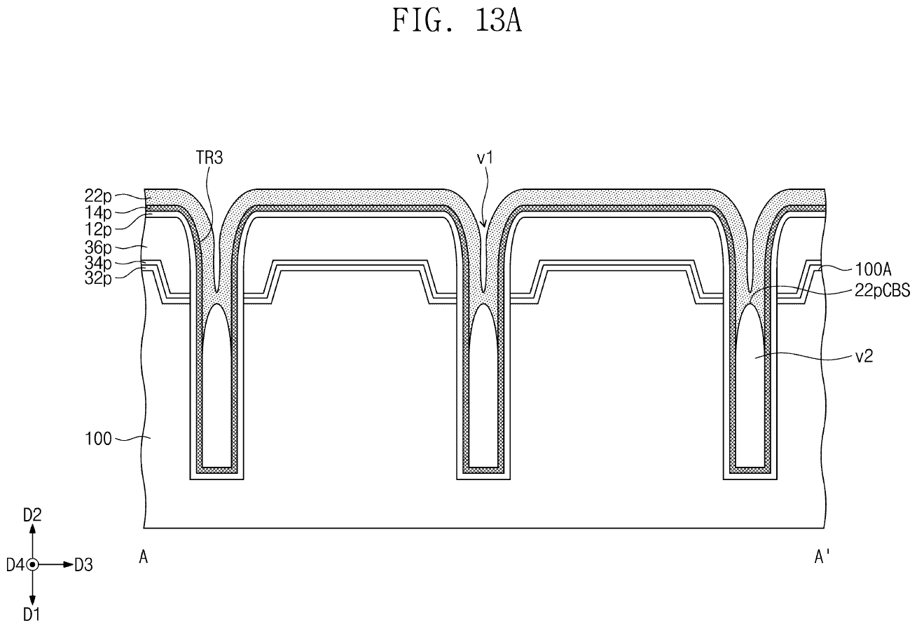

Referring to FIGS. 12A and 12B, a second insulating liner layer 14p may conformally cover an inner surface of the second trench TR2. The second insulating liner layer 14p may conformally cover a bottom surface of the second trench TR2 and may conformally cover a side surface of the second trench TR2. As a result of the formation of the second insulating liner layer 14p, a third trench TR3 may be formed.

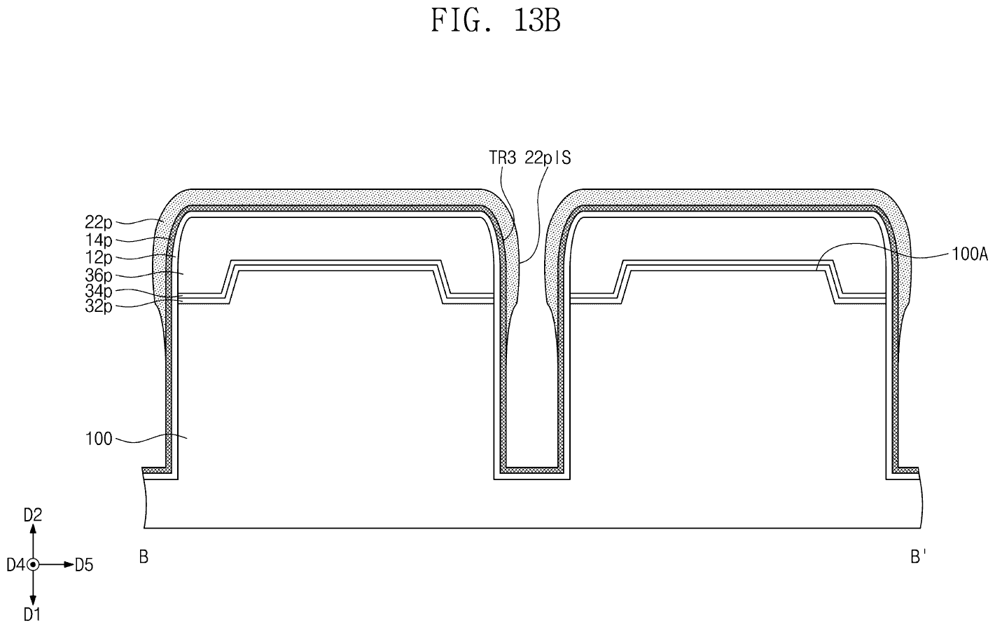

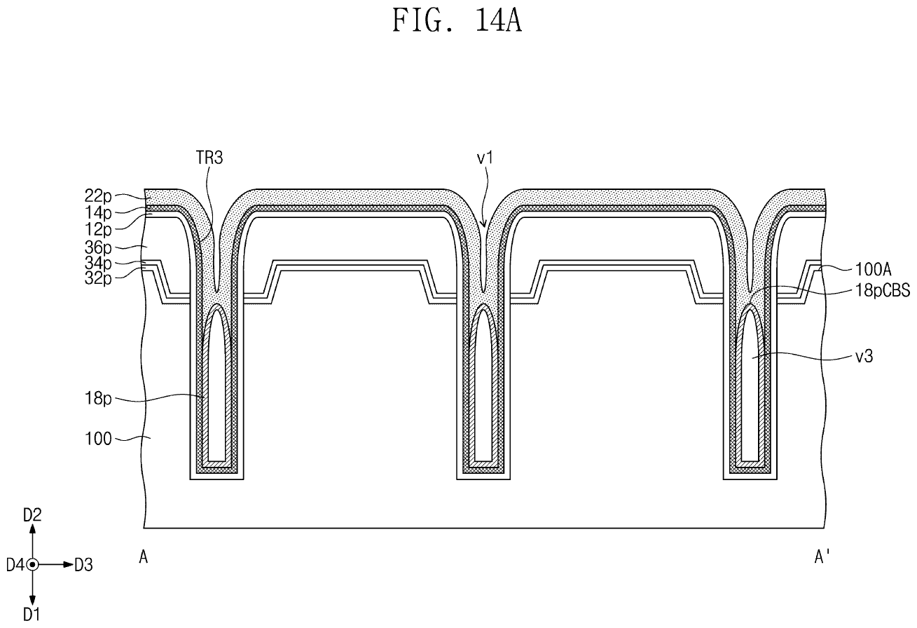

Referring to FIGS. 13A and 13B, a preliminary intervening insulating layer 22p may be formed. The preliminary intervening insulating layer 22p may be formed on the second insulating liner layer 14p.

In the intervening region IR, the preliminary intervening insulating layer 22p may be formed to fill an upper portion of the third trench TR3. Since the preliminary intervening insulating layer 22p is formed along the second insulating liner layer 14p, a first space portion v1 may be defined by two vertical portions of the preliminary intervening insulating layer 22p. Hereinafter, a lower portion of the third trench TR3, which is not filled with the preliminary intervening insulating layer 22p, may be referred to as a second space portion v2. A top surface 22pCBS of the second space portion v2 may include a curved surface.

In the intersecting region CR, the preliminary intervening insulating layer 22p may be formed on the second insulating liner layer 14p to fill an upper portion of the third trench TR3. As shown in FIG. 13B, the preliminary intervening insulating layer 22p may have inner surfaces 22pIS, which are spaced apart from each other, when viewed in a sectional view.

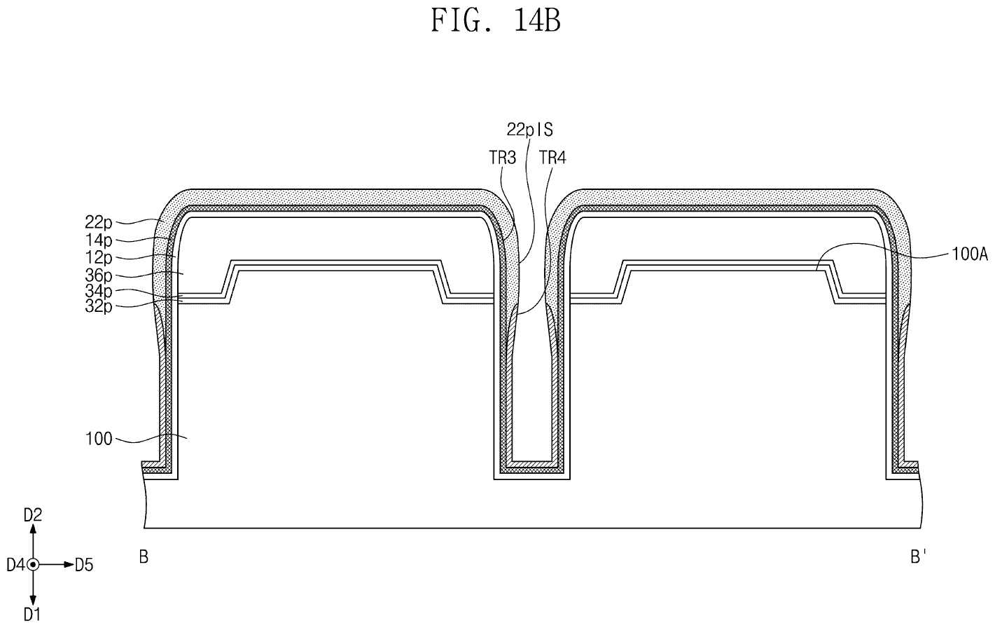

Referring to FIGS. 14A and 14B, in the intervening region IR, a preliminary conductive liner 18p may be formed to cover an inner surface of the second space portion v2. The preliminary conductive liner 18p may fill a portion of the second space portion v2, and in this case, a third space portion v3, which is surrounded by the preliminary conductive liner 18p, may be formed. A top surface 18pCBS of the preliminary conductive liner 18p may include a curved surface.

In the intersecting region CR, the preliminary conductive liner 18p may be formed to cover an exposed portion of the third trench TR3 and a portion of the inner surface 22pIS of the preliminary intervening insulating layer 22p. As a result of the formation of the preliminary conductive liner 18p, a fourth trench TR4 may be formed.

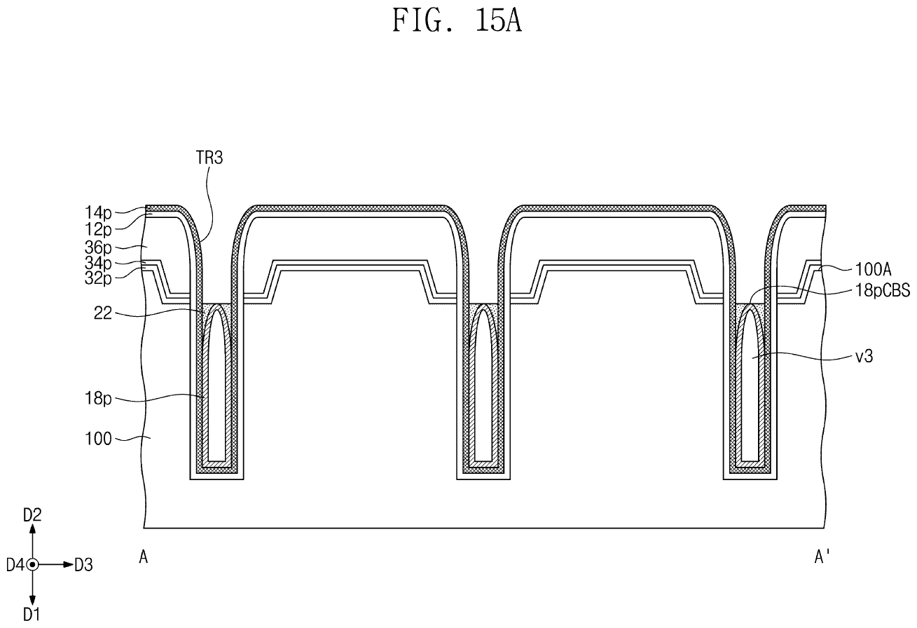

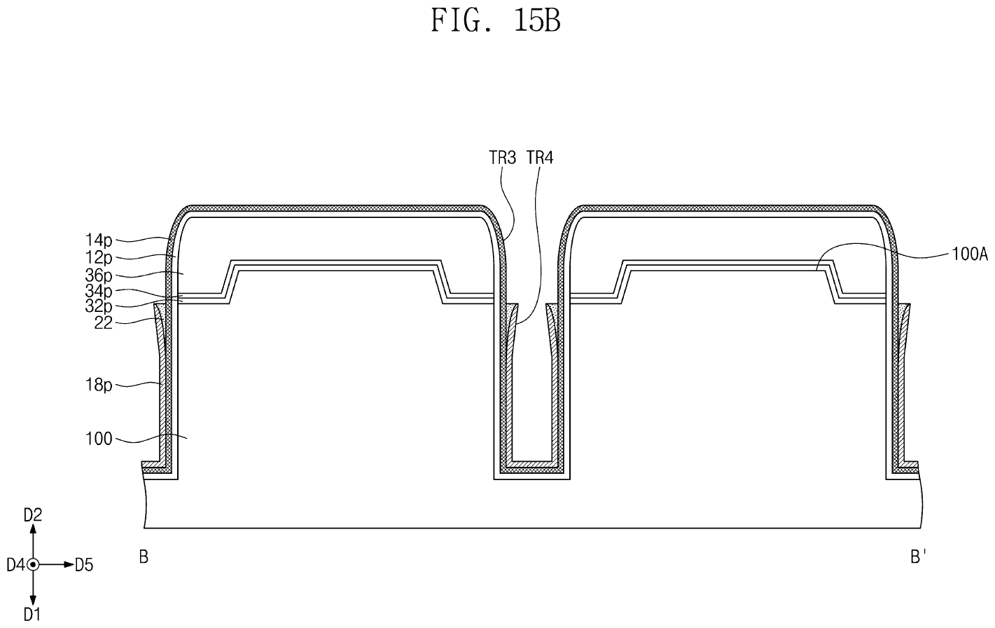

Referring to FIGS. 15A and 15B, a portion of the preliminary intervening insulating layer 22p may be removed. The second insulating liner layer 14p may be used as an etch stop layer when the preliminary intervening insulating layer 22p is removed. This process may be performed to etch a portion of the preliminary intervening insulating layer 22p, which is located at a level higher than the top surface 18pCBS of the preliminary conductive liner 18p. As a result of the removal of the preliminary conductive liner 18p, a portion of the third trench TR3 may be exposed. As a result of the etching of the preliminary intervening insulating layer 22p, the intervening insulating pattern 22 may be formed.

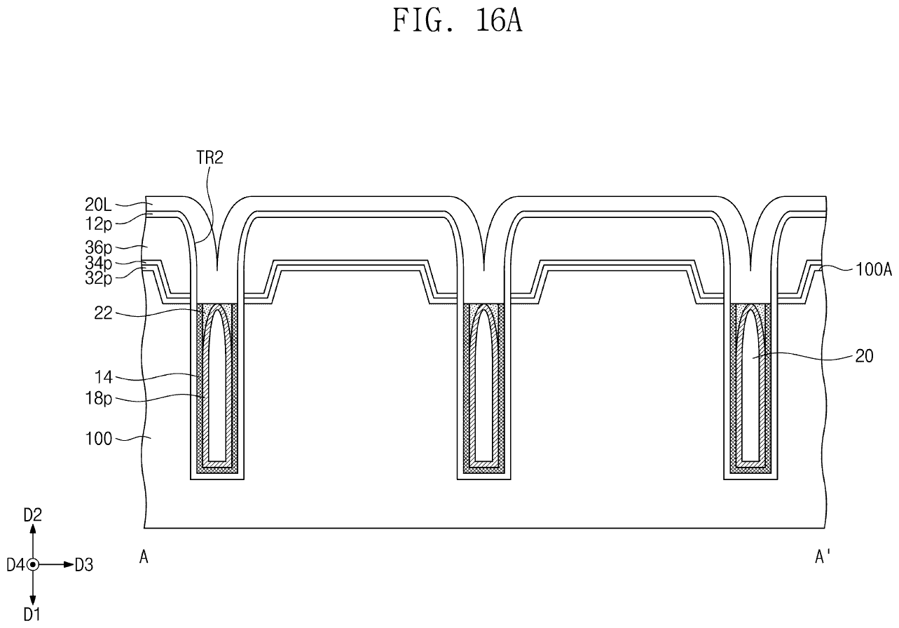

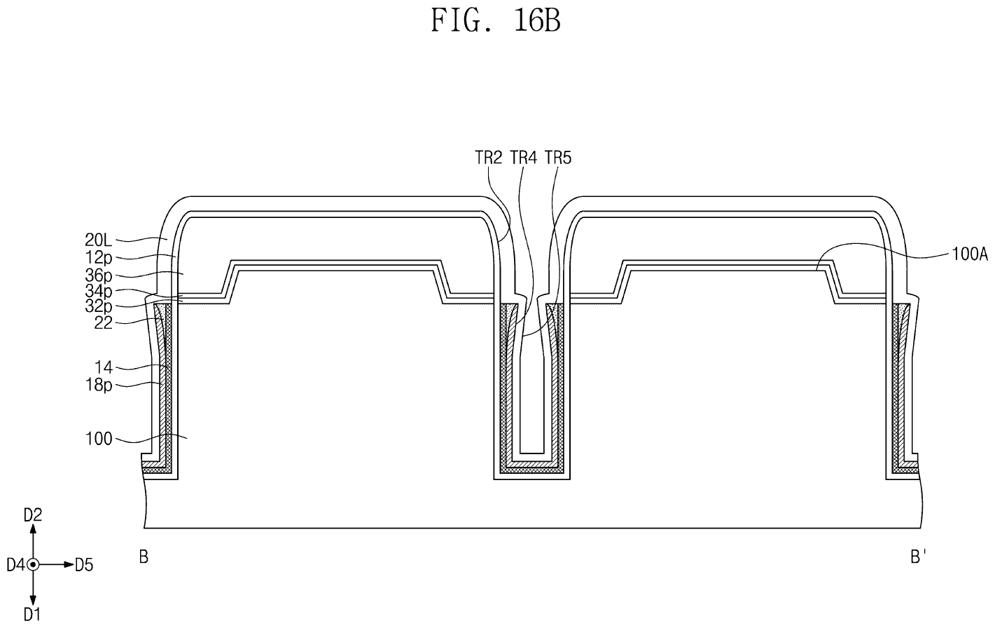

Referring to FIGS. 16A and 16B, the second insulating liner layer 14p may be removed. In some implementations, the removal of the second insulating liner layer 14p may be performed to leave a portion of the second insulating liner layer 14p, which is lower than the top surface of the intervening insulating pattern 22, and to remove only a portion of the second insulating liner layer 14p, which is higher than the top surface of the intervening insulating pattern 22. As a result of the removal of the second insulating liner layer 14p, the second trench TR2 may be exposed.

A preliminary insulating gapfill layer 20L may be formed on the second trench TR2, the intervening insulating pattern 22, and the preliminary conductive liner 18p. In the intervening region IR, the preliminary insulating gapfill layer 20L may be formed to fill the second trench TR2 and to cover the first insulating liner layer 12p. The preliminary insulating gapfill layer 20L may fill the third space portion v3 described above. Since the preliminary insulating gapfill layer 20L fills the third space portion v3, the insulating gapfill layer 20 may be formed.

In the intersecting region CR, the preliminary insulating gapfill layer 20L may be formed to cover top surfaces of the intervening insulating pattern 22 and the second insulating liner layer 14p and an inner side surface of the preliminary conductive liner 18p and to cover the second trench TR2 and the fourth trench TR4. As a result of the formation of the preliminary insulating gapfill layer 20L, a fifth trench TR5 may be formed.

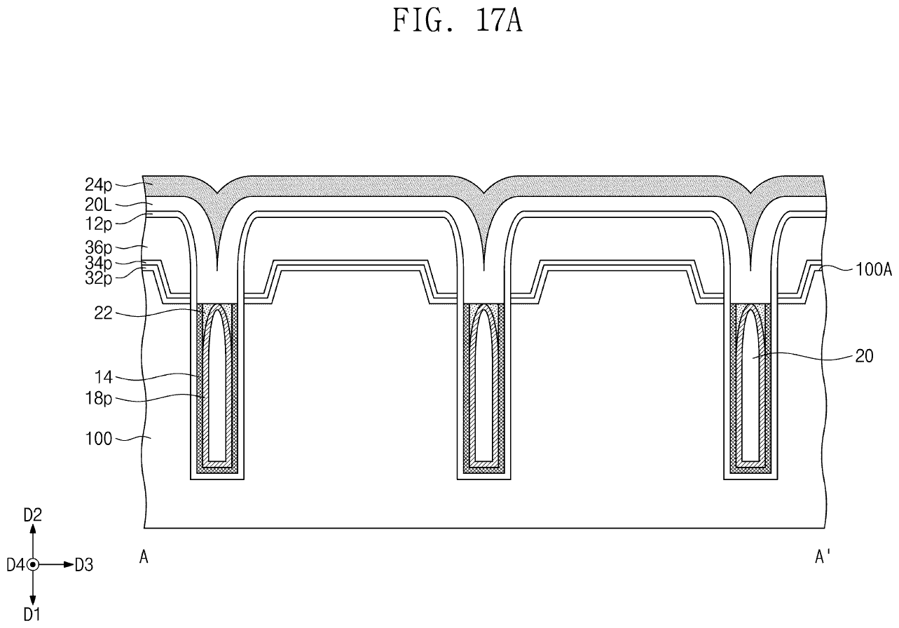

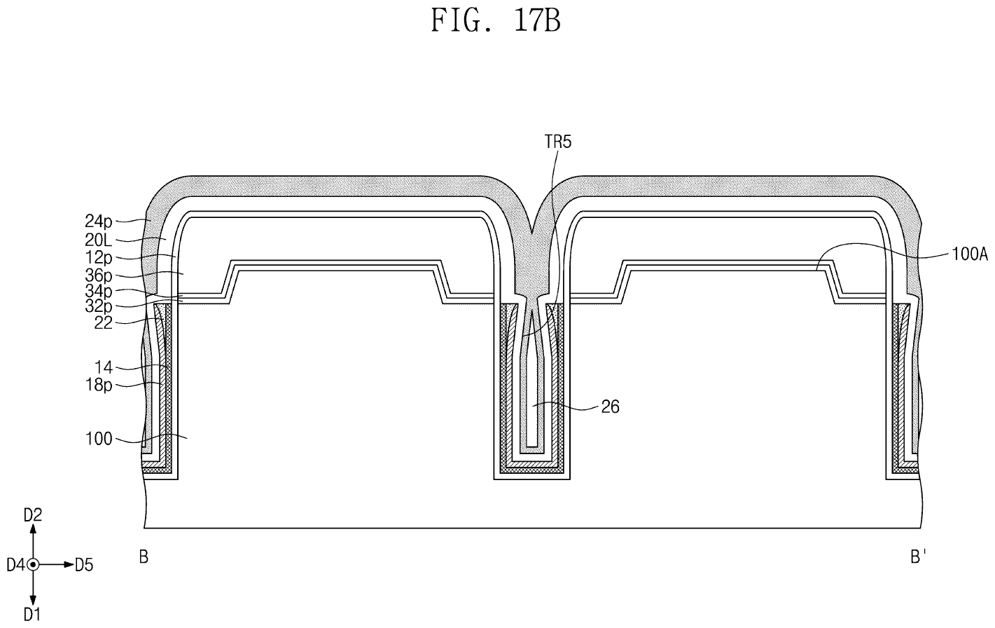

Referring to FIGS. 17A and 17B, a preliminary inner insulating layer 24p may be formed to cover the preliminary insulating gapfill layer 20L. In the intervening region IR, the preliminary inner insulating layer 24p may be formed to fully cover a top surface of the preliminary insulating gapfill layer 20L. In the intersecting region CR, the preliminary inner insulating layer 24p may be formed to cover the preliminary insulating gapfill layer 20L and the fifth trench TR5. The preliminary inner insulating layer 24p may be formed to cover bottom and inner surfaces of the fifth trench TR5 but may not fill the entirety of the fifth trench TR5. The preliminary inner insulating layer 24p may be formed to fully fill a space that is defined by the preliminary insulating gapfill layer 20L and is formed at a level higher than the top surface of the intervening insulating pattern 22. The preliminary inner insulating layer 24p may be formed to cover a bottom surface and an inner surface of the fifth trench TR5 but not to fill the entirety of the fifth trench TR5, and as a result, the gap portion 26 may be formed in the fifth trench TR5.

Referring to FIGS. 18A and 18B, a planarization process may be performed. The planarization process may include performing a chemical mechanical polishing (CMP) process. The first insulating pattern 12, the first isolation portion 32, the second isolation portion 34, and the third isolation portion 36 may be formed by removing upper portions of the first insulating liner layer 12p, the preliminary insulating gapfill layer 20L, the first isolation layer 32p, the second isolation layer 34p, and the third isolation layer 36p through the planarization process.

Thereafter, a planarization process may be performed to remove a lower portion of the first insulating liner layer 12p, a lower portion of the second insulating liner layer 14p, a lower portion of the preliminary conductive liner layer 18p and to expose a bottom surface of the gapfill insulating pattern 20. Thus, the second insulating liner 14 and the conductive liner 18 may be formed. The first and second surfaces 100A and 100B of the substrate 100 may be exposed.

Thereafter, the anti-reflection layer 42 on the second surface 100B of the substrate 100, the light-blocking patterns 48 on the anti-reflection layer 42, and the low refractive patterns 50 on the light-blocking patterns 48 may be formed. The color filters CF1 and CF2 may be formed between the low refractive patterns 50. The micro lenses ML may be formed on the color filters CF1 and CF2.

The interlayer insulating layer ILD and the interconnection lines 60 may be formed on the first surface 100A of the substrate 100, and as a result, the image sensor may be formed to have the structure of FIGS. 3 to 5B.

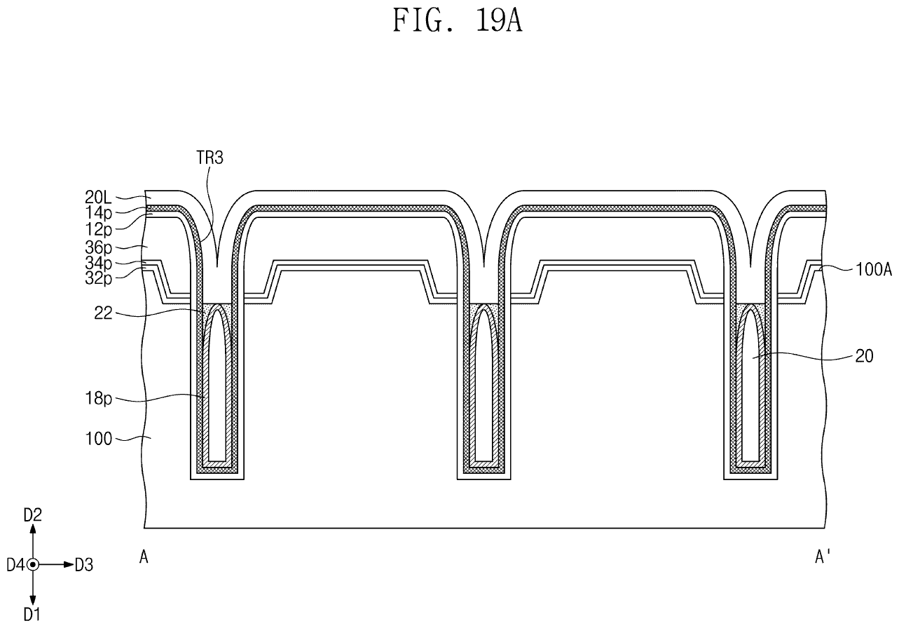

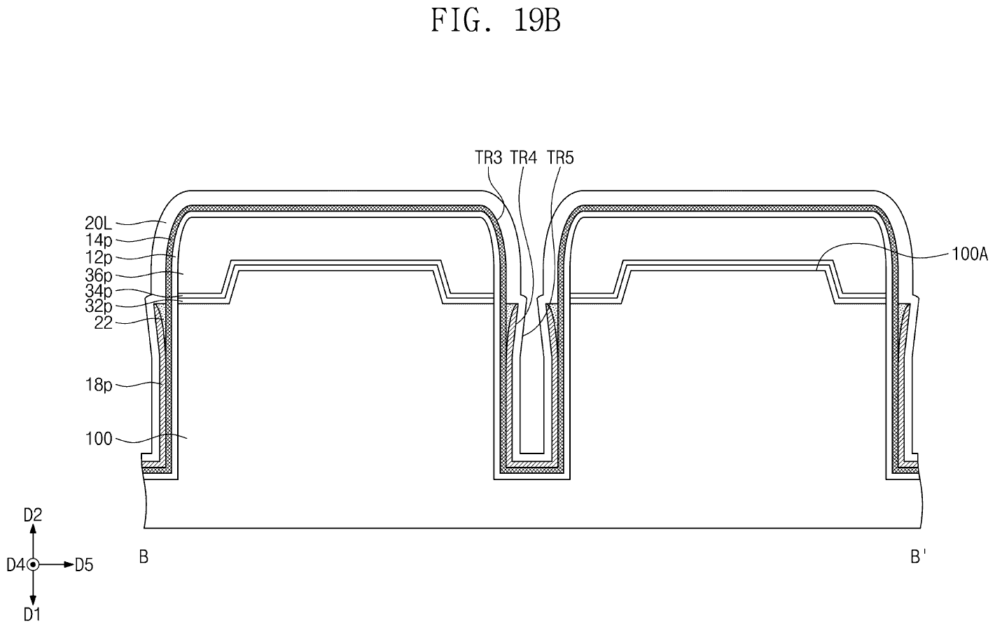

FIGS. 19A to 23A and FIGS. 19B to 23B are sectional views illustrating a method of fabricating an image sensor, according to some implementations and corresponding to the lines A-A′ and B-B′ of FIG. 4, respectively. For concise description, a previously described element may be identified by the same reference number without repeating an overlapping description thereof.

Hereinafter, a method of fabricating the image sensor of FIG. 6 will be described with reference to FIGS. 19A and 19B. The steps described with reference to FIGS. 11A to 15A and 11B to 15B may be performed in the same manner in this method. A portion of the preliminary intervening insulating layer 22p may be removed to form the intervening insulating pattern 22.

Referring back to FIGS. 19A and 19B, the preliminary insulating gapfill layer 20L may be formed on the structure with the second insulating liner layer 14p. In the intervening region IR, the preliminary insulating gapfill layer 20L may be formed to fully fill the third trench TR3. The preliminary insulating gapfill layer 20L may be formed to fill the third space portion v3, and thus, the gapfill insulating pattern 20 may be formed.

In the intersecting region CR, the preliminary insulating gapfill layer 20L may be formed to cover the top surface of the second insulating liner layer 14p, the top surface of the intervening insulating pattern 22, and an inner surface of the conductive liner 18. The preliminary insulating gapfill layer 20L may be formed on the third trench TR3 and the fourth trench TR4. Thus, the fifth trench TR5 may be formed in the intersecting region CR.

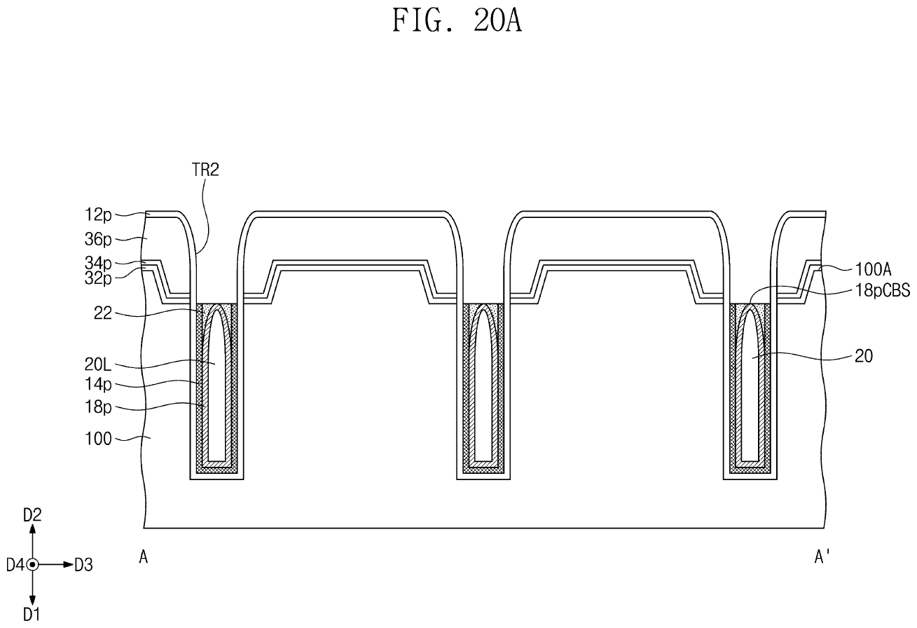

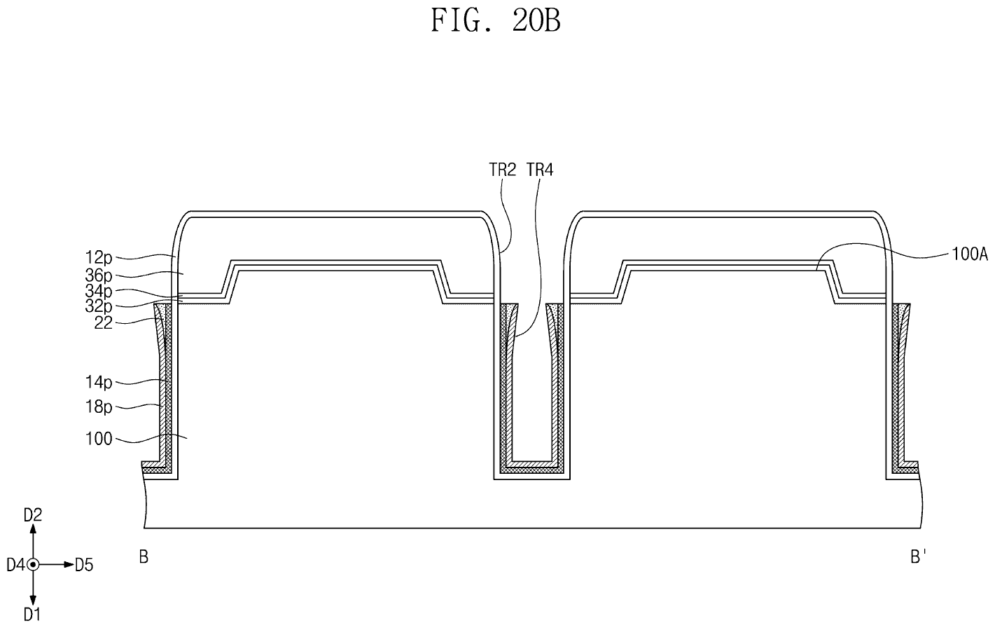

Referring to FIGS. 20A and 20B, the preliminary insulating gapfill layer 20L may be removed. The second insulating liner layer 14p may be removed. The preliminary insulating gapfill layer 20L and the second insulating liner layer 14p may be removed from a region that is higher than a top surface of the conductive liner 18. The second trench TR2 and the fourth trench TR4 may be exposed.

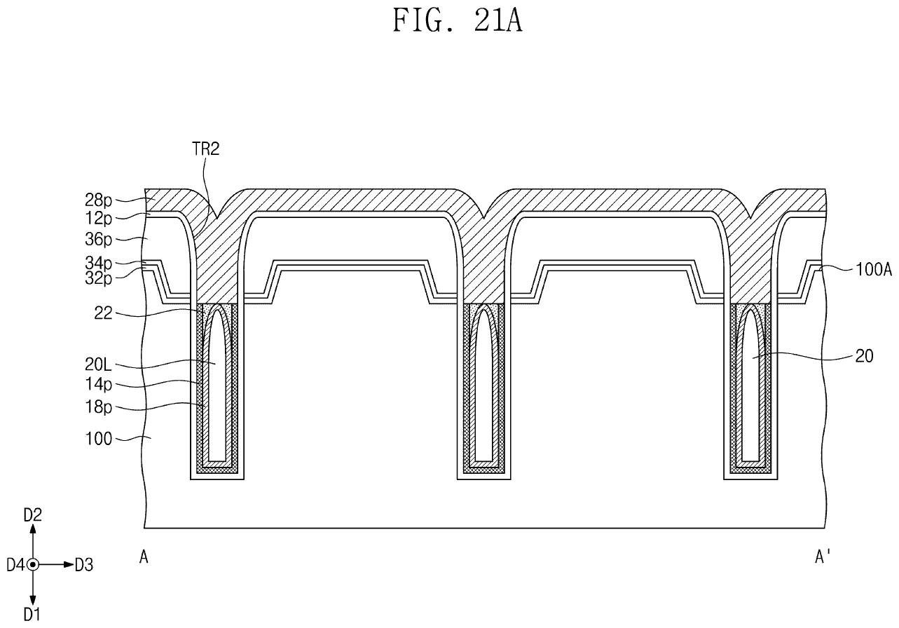

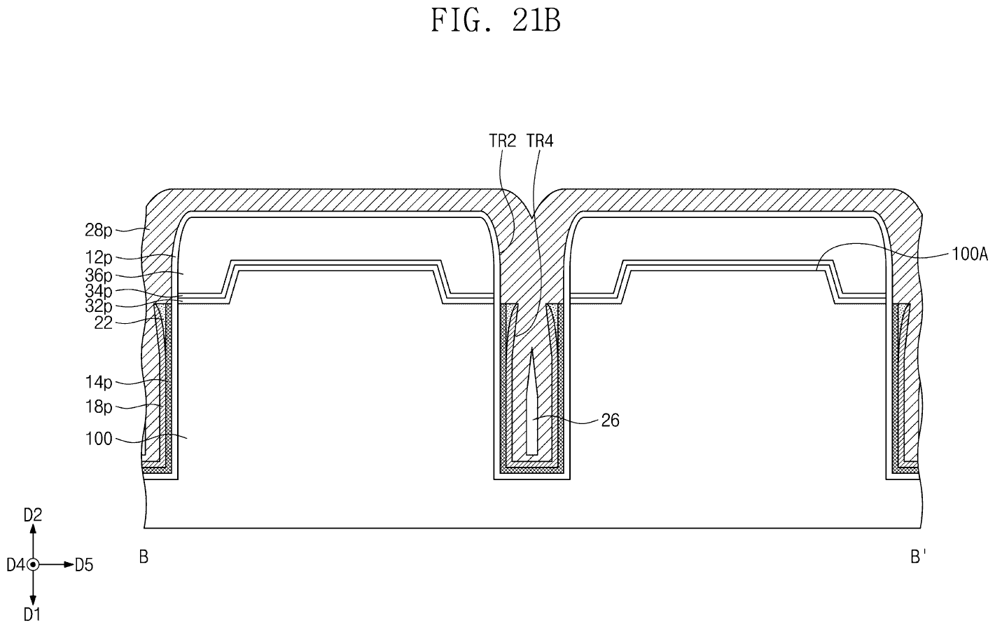

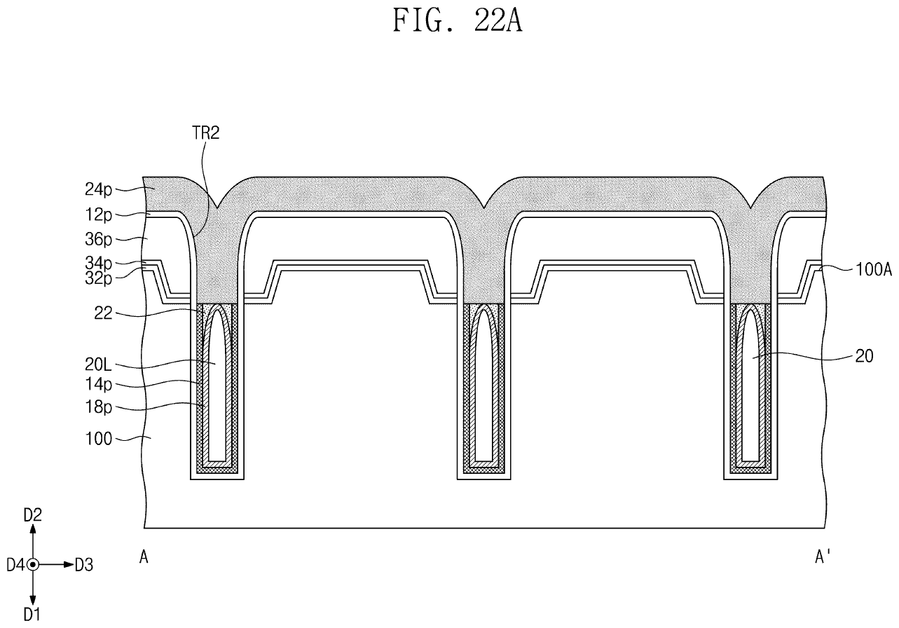

Referring to FIGS. 21A and 21B, the preliminary gapfill layer 28p may be formed on the second trench TR2 and the fourth trench TR4. In the intervening region IR, the preliminary gapfill layer 28p may be formed to fully fill the second trench TR2.

In the intersecting region CR, the preliminary gapfill layer 28p may be formed to cover an inner surface of the fourth trench TR4 and to fill a portion of the fourth trench TR4. Since the preliminary gapfill layer 28p does not fill a portion of the fourth trench TR4, the gap portion 26 may be formed.

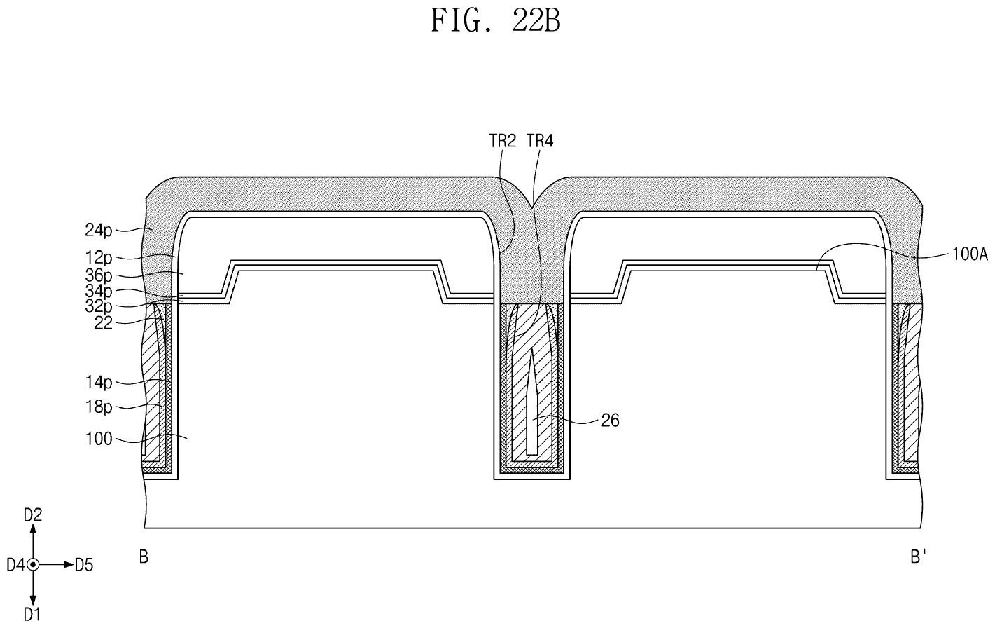

Referring to FIGS. 22A and 22B, the preliminary gapfill layer 28p may be removed from a region that is higher than the top surface of the conductive liner 18. The second trench TR may be exposed. Next, the preliminary inner insulating pattern 24p may be formed on the first insulating liner 12p to fill the expose second trench TR.

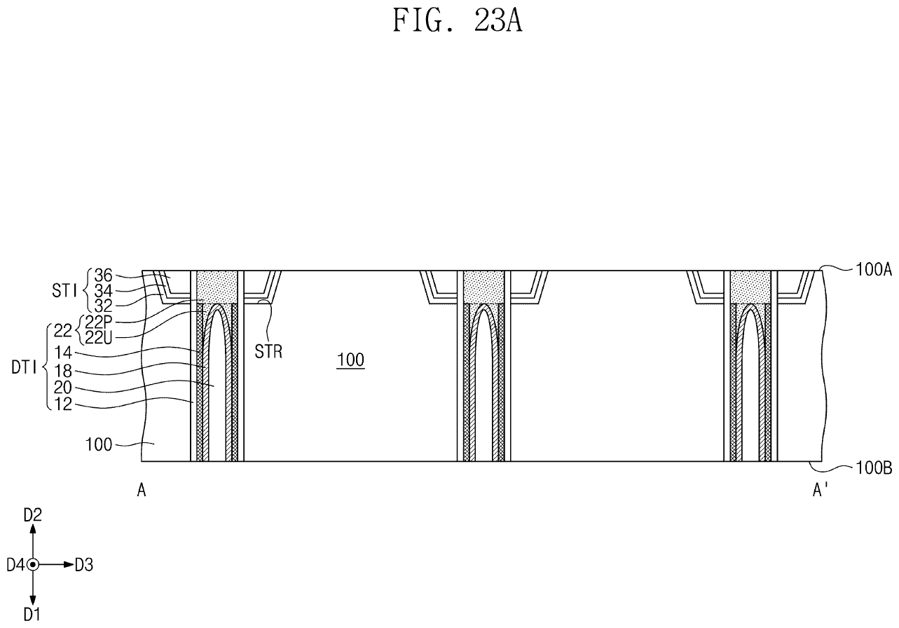

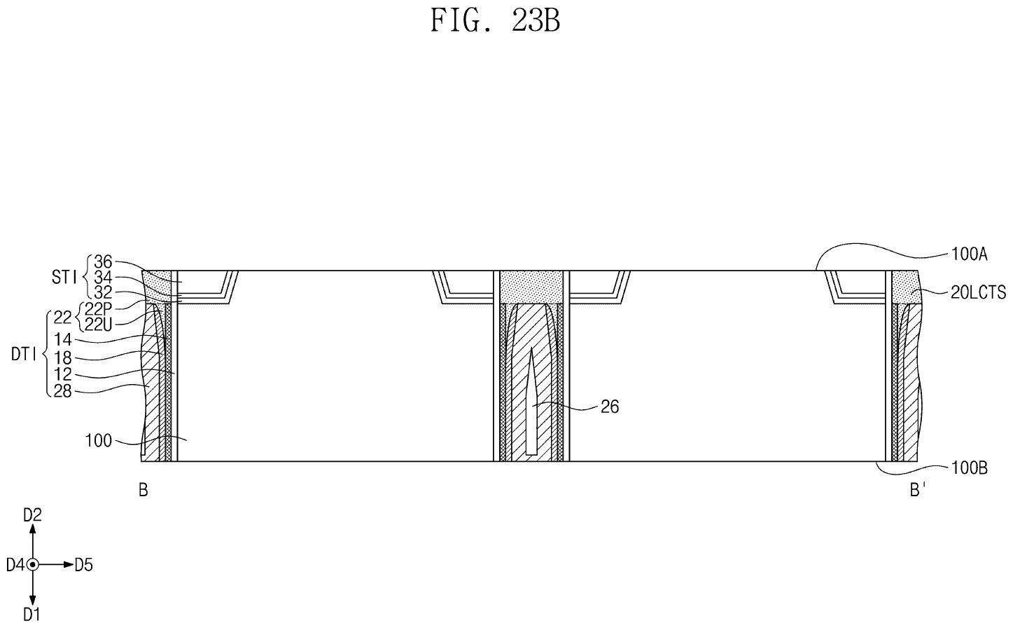

Referring to FIGS. 23A and 23B, a planarization process may be performed. The planarization process may include performing a chemical mechanical polishing (CMP) process. The first insulating pattern 12, the first isolation portion 32, the second isolation portion 34, and the third isolation portion 36 may be formed by removing upper portions of the first insulating liner layer 12p, the preliminary inner insulating layer 24p, and the first isolation layer 32p, the second isolation layer 34p, and the third isolation layer 36p through the planarization process.

Thereafter, a planarization process may be performed to remove a lower portion of the first insulating liner layer 12p, a lower portion of the second insulating liner layer 14p, a lower portion of the preliminary conductive liner layer 18p and to expose a bottom surface of the gapfill insulating pattern 20. Thus, the second insulating liner 14 and the conductive liner 18 may be formed. The first and second surfaces 100A and 100B of the substrate 100 may be exposed.

Thereafter, the anti-reflection layer 42 on the second surface 100B of the substrate 100, the light-blocking patterns 48 on the anti-reflection layer 42, and the low refractive patterns 50 on the light-blocking patterns 48 may be formed. The color filters CF1 and CF2 may be formed between the low refractive patterns 50. The micro lenses ML may be formed on the color filters CF1 and CF2.

The interlayer insulating layer ILD and the interconnection lines 60 may be formed on the first surface 100A of the substrate 100, and the image sensor of FIG. 6 may be formed.

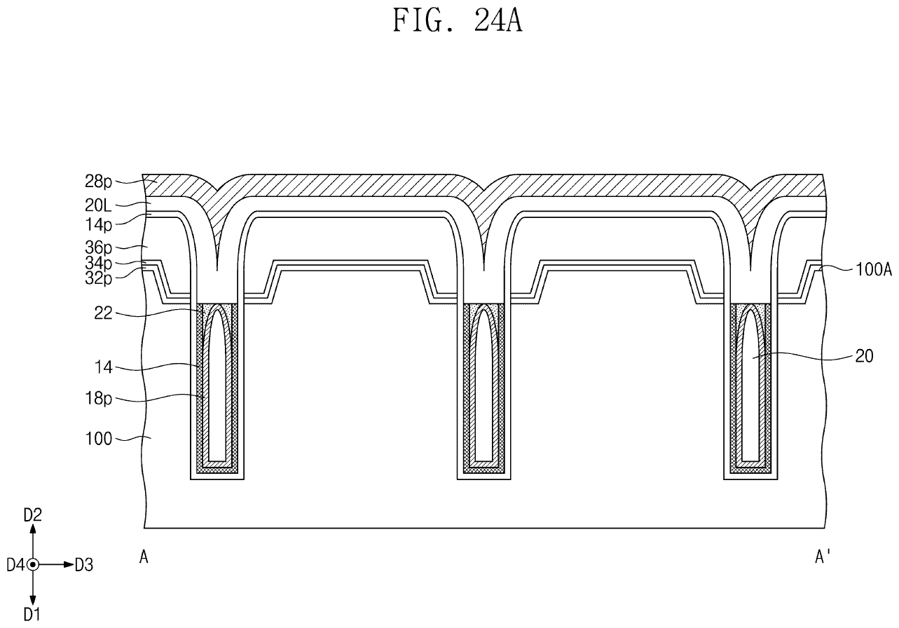

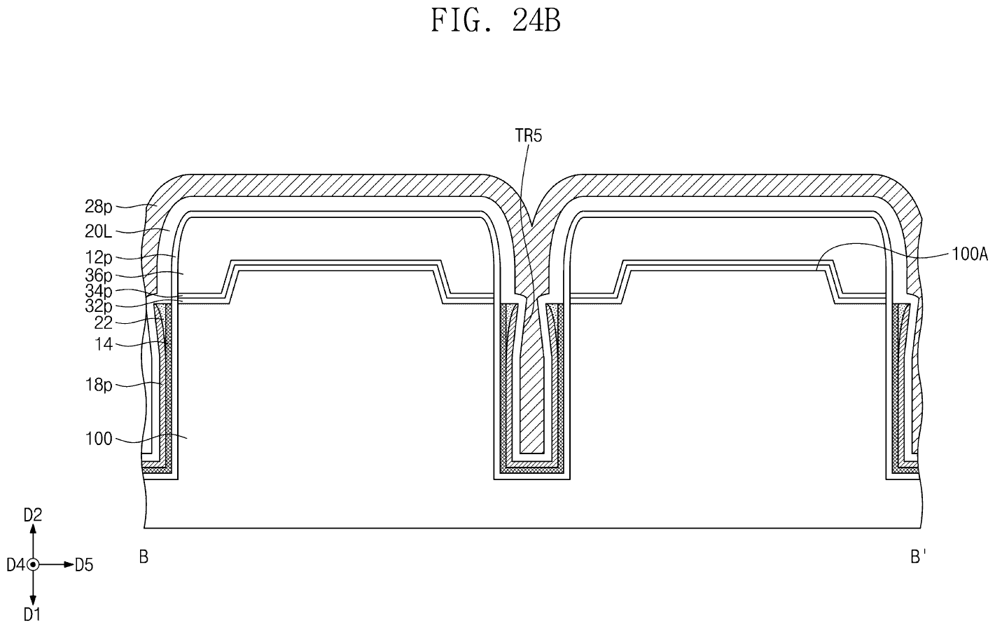

FIGS. 24A to 26A and FIGS. 24B to 26B are sectional views illustrating a method of fabricating an image sensor, according to some implementations and corresponding to the lines A-A′ and B-B′ of FIG. 4, respectively. For concise description, a previously described element may be identified by the same reference number without repeating an overlapping description thereof.

FIGS. 24A and 24B illustrate a method for manufacturing an image sensor according to the some implementations of FIG. 7. To manufacture an image sensor according to the some implementations of FIG. 7, the steps described with reference to FIGS. 11A to 16A and 11B to 16B may be performed in the same manner in this method. The preliminary gapfill insulating pattern 20L may be formed on the first insulating liner layer 12p. The gapfill insulating pattern 20 may be formed to fill the third space portion v3.

In the intervening region IR, the preliminary gapfill layer 28p may be formed on the preliminary gapfill insulating pattern 20L. The preliminary gapfill layer 28p may be formed to cover a top surface of the preliminary gapfill insulating pattern 20L.

In the intersecting region CR, the preliminary gapfill layer 28p may be formed to fill an unfilled region of the fifth trench TR5 covered with the preliminary gapfill insulating pattern 20L. The preliminary gapfill layer 28p may be formed not to fill a portion of the fifth trench TR5, and thus, a gap portion may be formed.

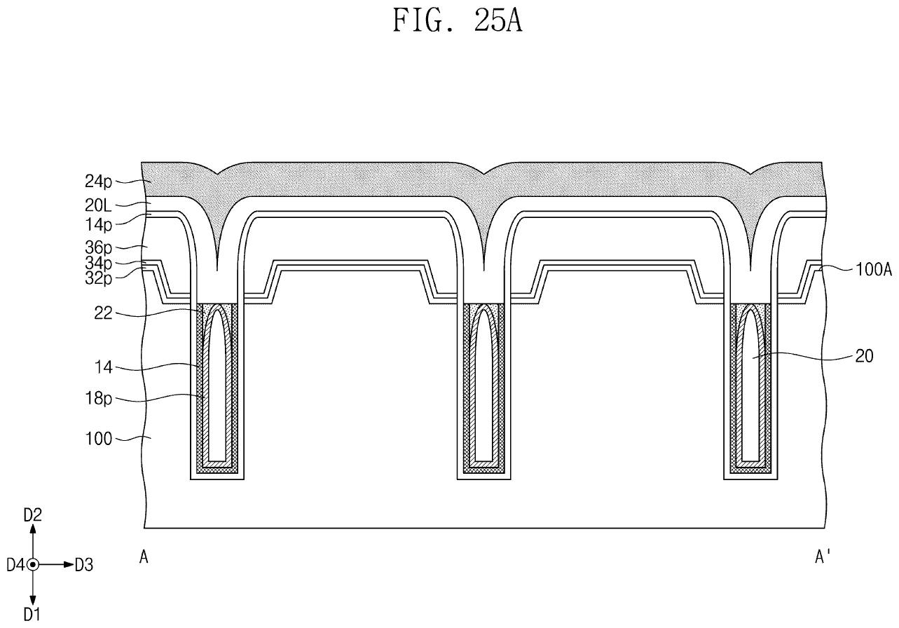

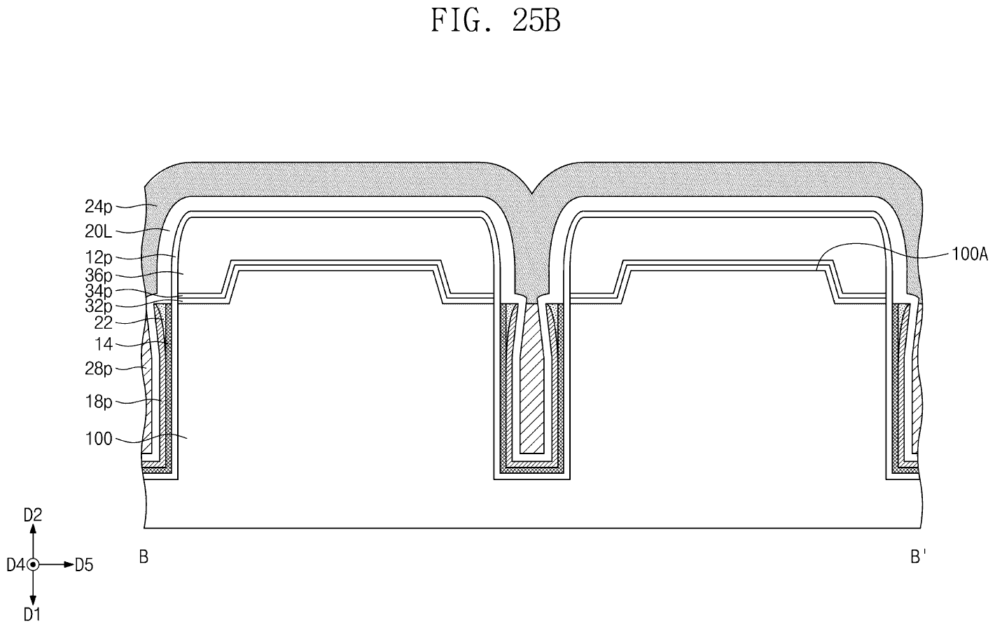

Referring to FIGS. 25A and 25B, the preliminary gapfill layer 28p may be removed.

In the intervening region IR, the preliminary gapfill layer 28p on the top surface of the preliminary gapfill insulating pattern 20L may be fully removed, and the preliminary inner insulating layer 24p may be formed to cover the top surface of the preliminary gapfill insulating pattern 20L.

In the intersecting region CR, the preliminary gapfill layer 28p, which is located at a level higher than the top surface of the intervening insulating pattern 22, may be removed. Next, the preliminary inner insulating layer 24p may be formed to cover an exposed top surface of the preliminary gapfill layer 28p and an exposed top surface of the preliminary gapfill insulating pattern 20L.

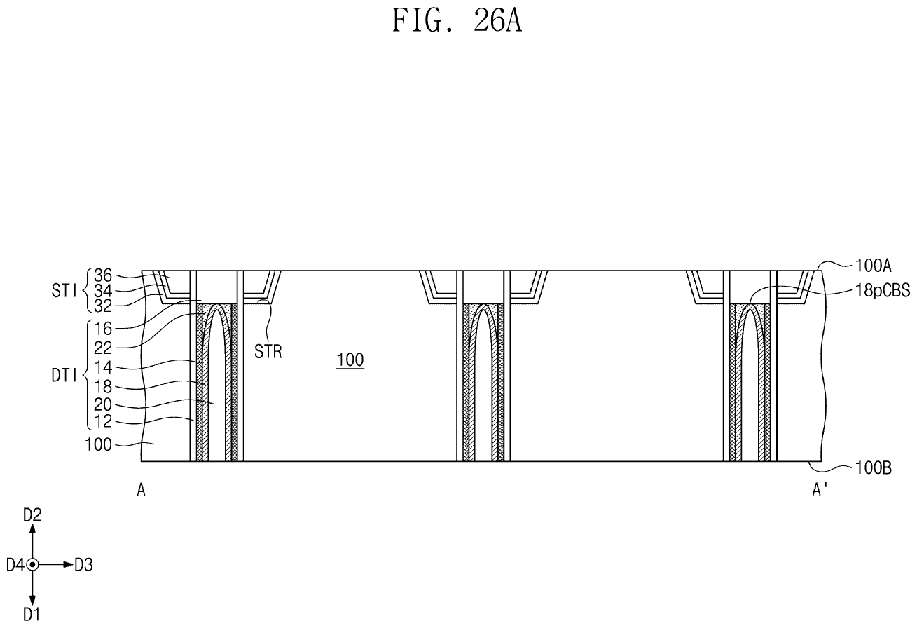

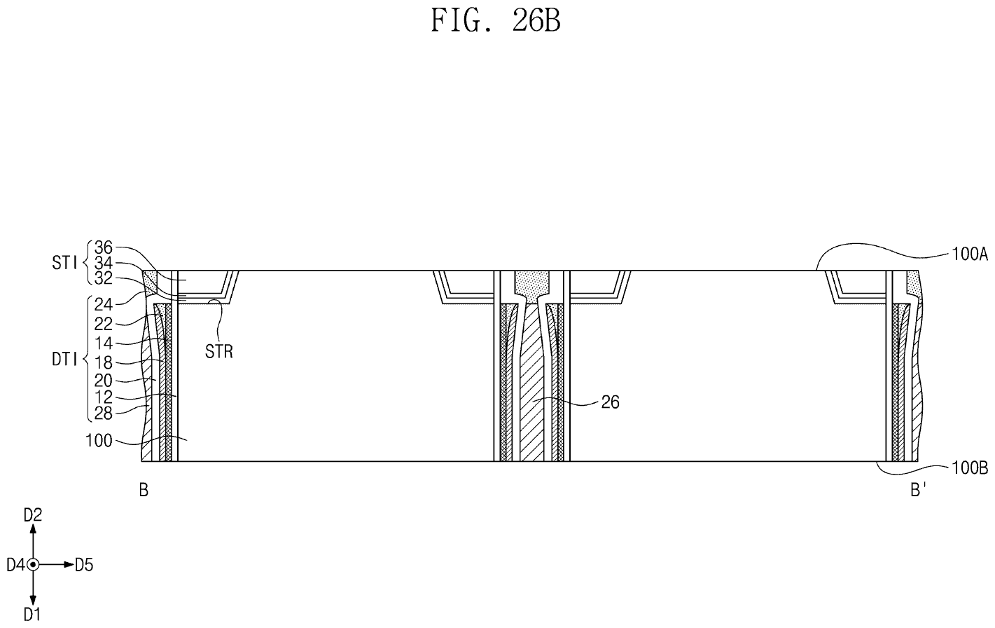

Referring to FIGS. 26A and 26B, a planarization process may be performed in a similar manner to the process described above. In this case, the image sensor may be formed to have the structure of FIG. 7.

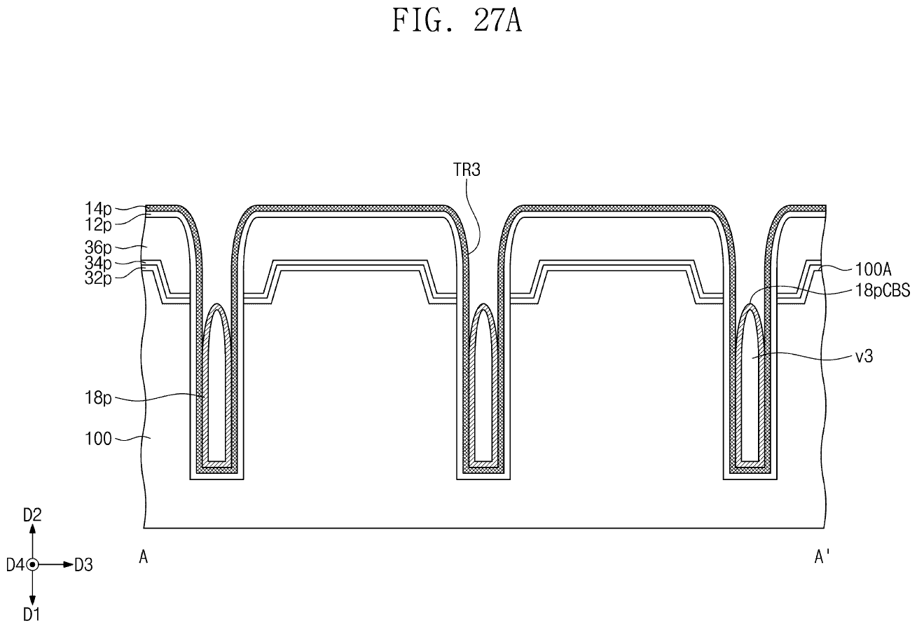

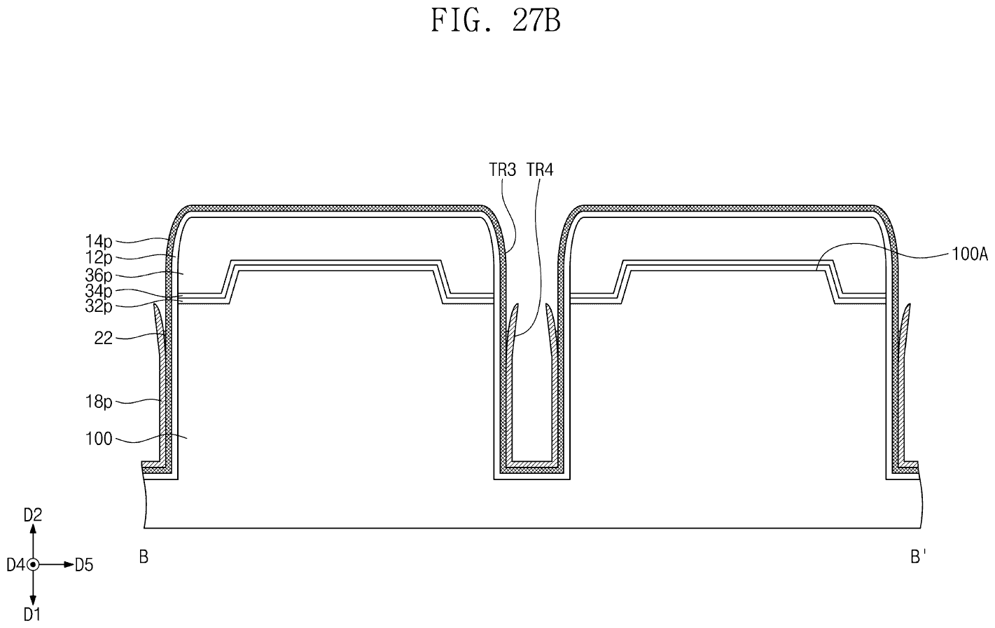

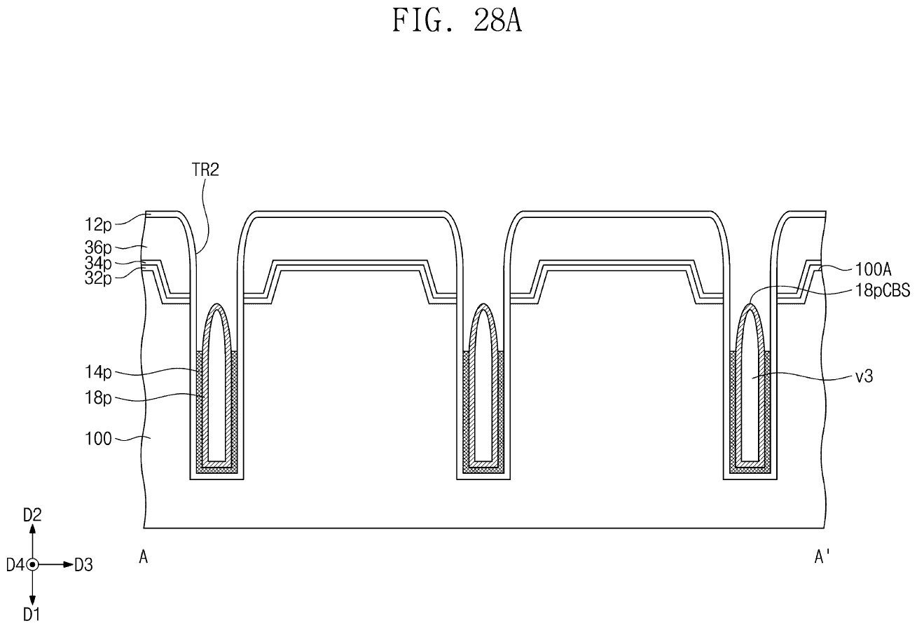

FIGS. 27A to 31A and FIGS. 27B to 31B are sectional views illustrating a method of fabricating an image sensor, according to some implementations and corresponding to the lines A-A′ and B-B′ of FIG. 4, respectively. For concise description, a previously described element may be identified by the same reference number without repeating an overlapping description thereof.

FIGS. 27A and 27B illustrate a method for manufacturing an image sensor according to the some implementations of FIGS. 8A and 8B. To manufacture an image sensor according to the some implementations of FIGS. 8A and 8B, the steps described with reference to FIGS. 11A to 14A and 11B to 14B may be performed in the same manner in this method.

Referring to FIGS. 27A and 27B, the preliminary intervening insulating pattern 22p, which is formed on the second insulating liner 14p, may be removed, after the formation of the preliminary conductive liner 18p. A top surface of the preliminary conductive liner 18p and a top surface of the second insulating liner 14p may be exposed. The third trench TR3 and the fourth trench TR4 may be exposed.

The preliminary intervening insulating pattern 22p may be fully removed from the intervening region IR. In the intervening region IR, the third space portion v3 may remain empty.

In the intersecting region CR, a portion of the preliminary intervening insulating pattern 22p may form the intervening insulating pattern 22, which is left between the preliminary conductive liner 18p and the first insulating liner layer 12p.

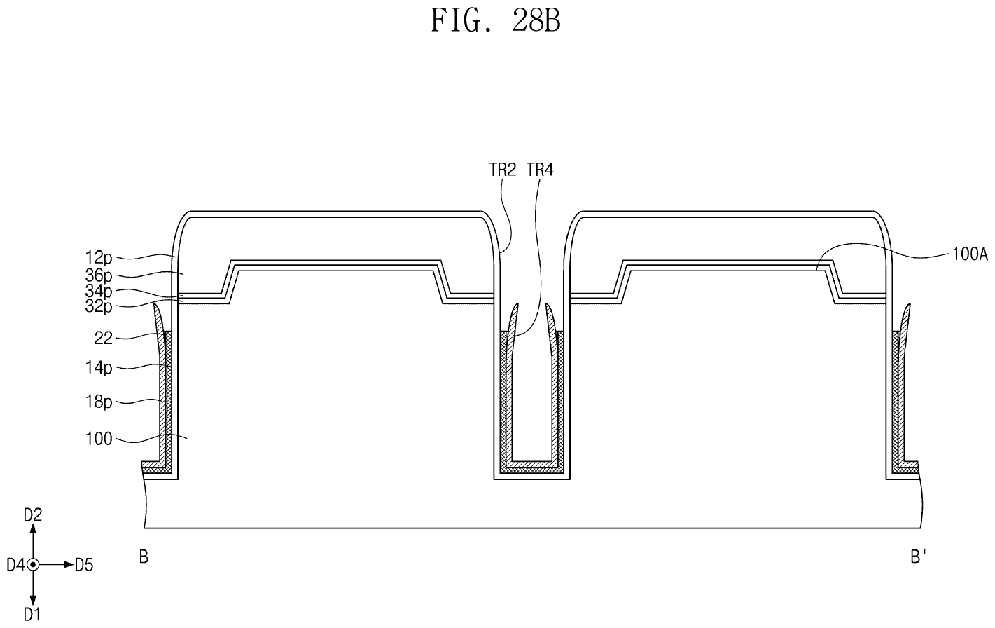

Referring to FIGS. 28A and 28B, the second insulating liner 14p may be removed. The second insulating liner 14p may be etched using, for example, phosphoric acid. The second insulating liner 14p may be recessed to a level lower than the topmost surface of the preliminary conductive liner 18p. In other words, a distance from the first surface 100A of the substrate 100 to the remaining portion of the second insulating liner 14p may be larger than a distance from the first surface 100A of the substrate 100 to the topmost surface of the preliminary conductive liner 18p.

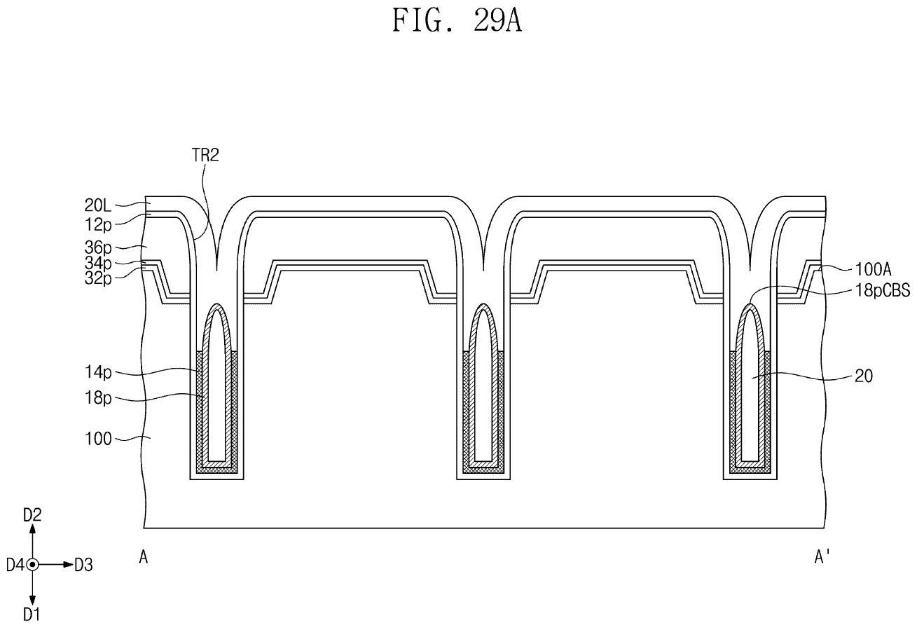

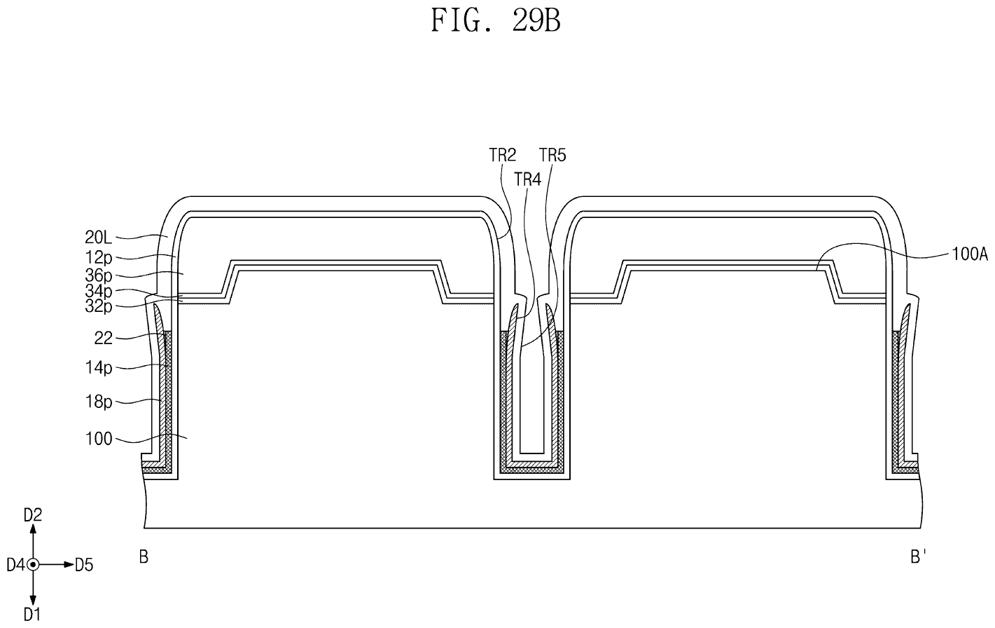

Referring to FIGS. 29A and 29B, the preliminary gapfill insulating pattern 20L may be formed on the first insulating liner layer 12p.

In the intervening region IR, the preliminary gapfill insulating pattern 20L may be formed to fully cover the first insulating liner layer 12p and to fill the third space portion v3. As a result, the gapfill insulating pattern 20 may be formed in the third space portion v3.

In the intersecting region CR, the preliminary gapfill insulating pattern 20L may be formed to cover inner surfaces of the second and fourth trenches TR2 and TR4, which are exposed to the outside. As a result, the fifth trench TR5 may be formed.

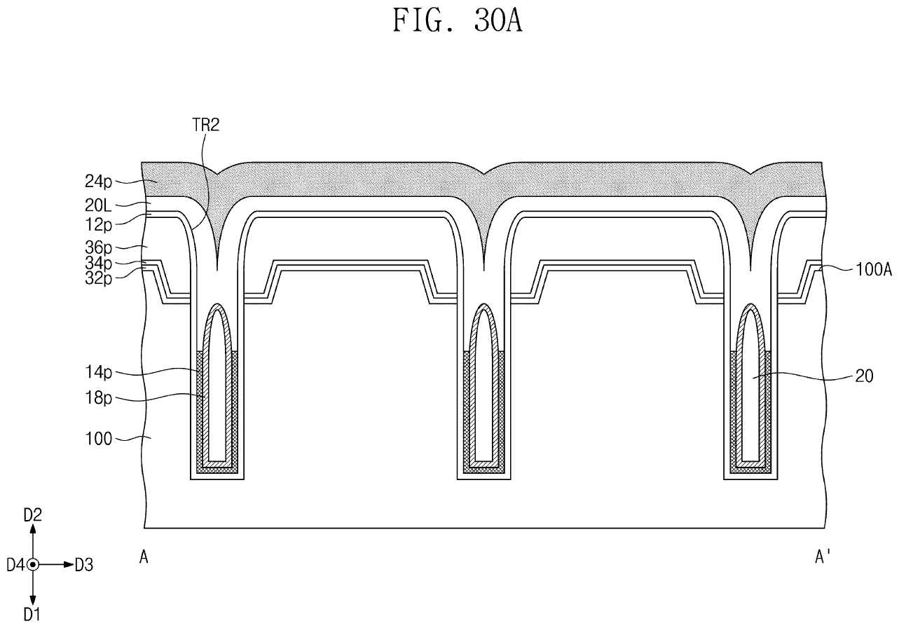

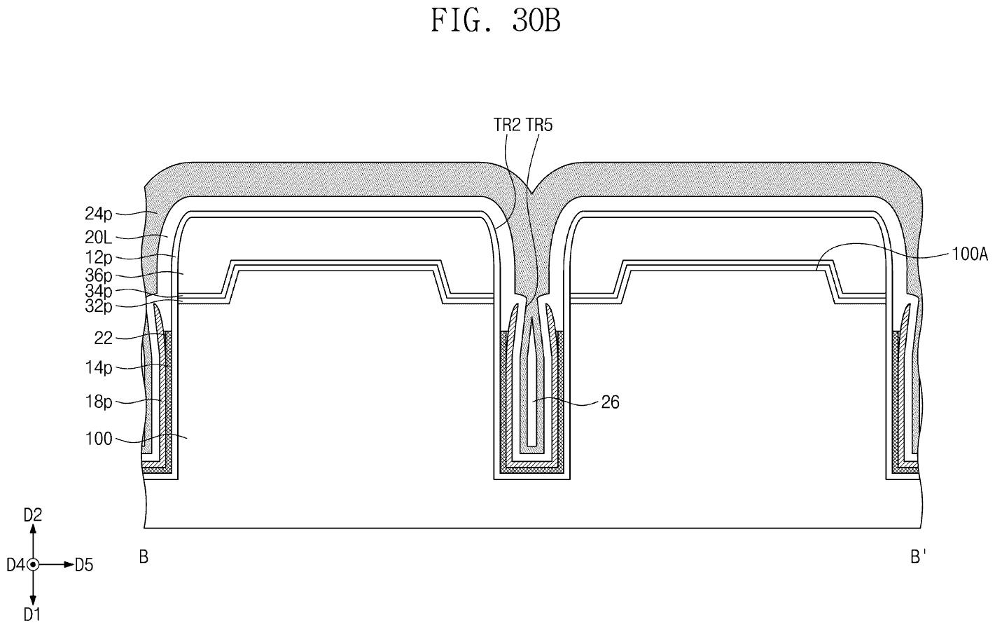

Referring to FIGS. 30A and 30B, the preliminary inner insulating layer 24p may be formed on the preliminary gapfill insulating pattern 20L.

In the intervening region IR, the preliminary inner insulating layer 24p may be formed to cover the top surface of the preliminary gapfill insulating pattern 20L.

In the intersecting region CR, the preliminary inner insulating layer 24p may be formed to cover the top surface of the preliminary gapfill insulating pattern 20L exposed to the outside. The preliminary inner insulating layer 24p may be formed to cover an exposed inner surface of the fifth trench TR5 and to fill a portion of the fifth trench TR5. Since the preliminary inner insulating layer 24p does not fill a portion of the fifth trench TR5, the gap portion 26 may be formed.

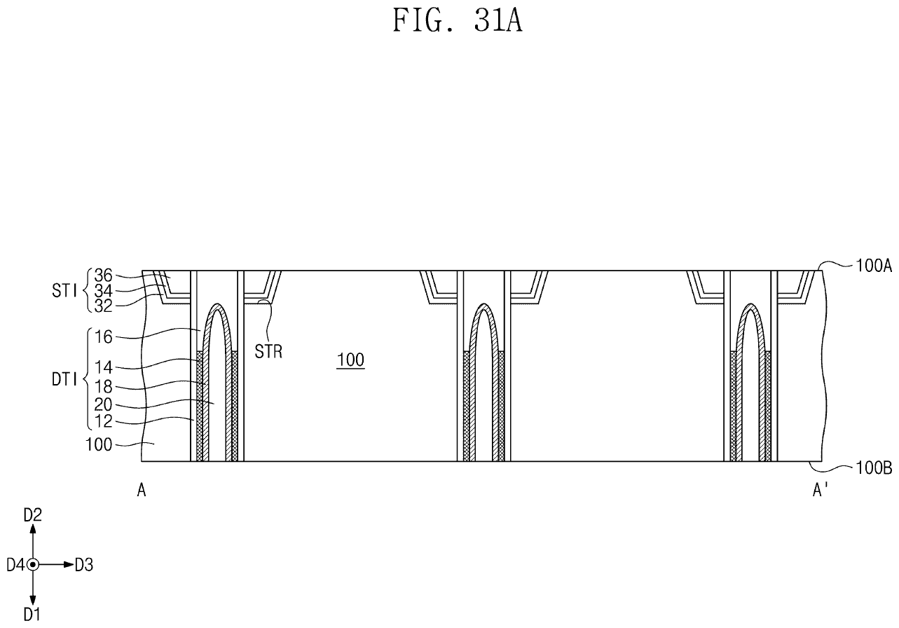

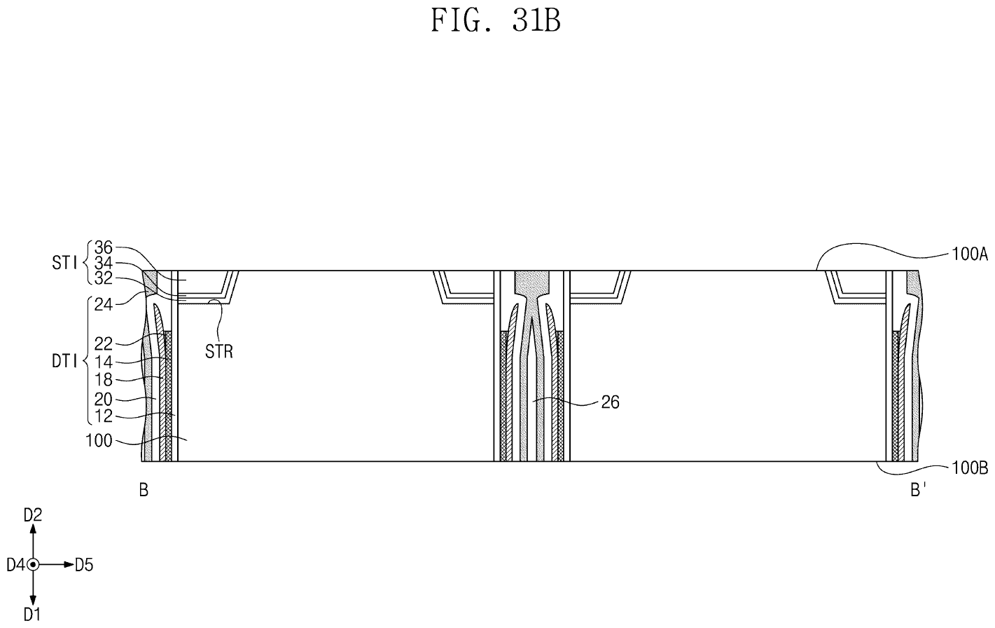

Referring to FIGS. 31A and 31B, a planarization process may be performed in a similar manner to the process described above. In this case, the image sensor may be formed to have the structure of FIGS. 8A and 8B.

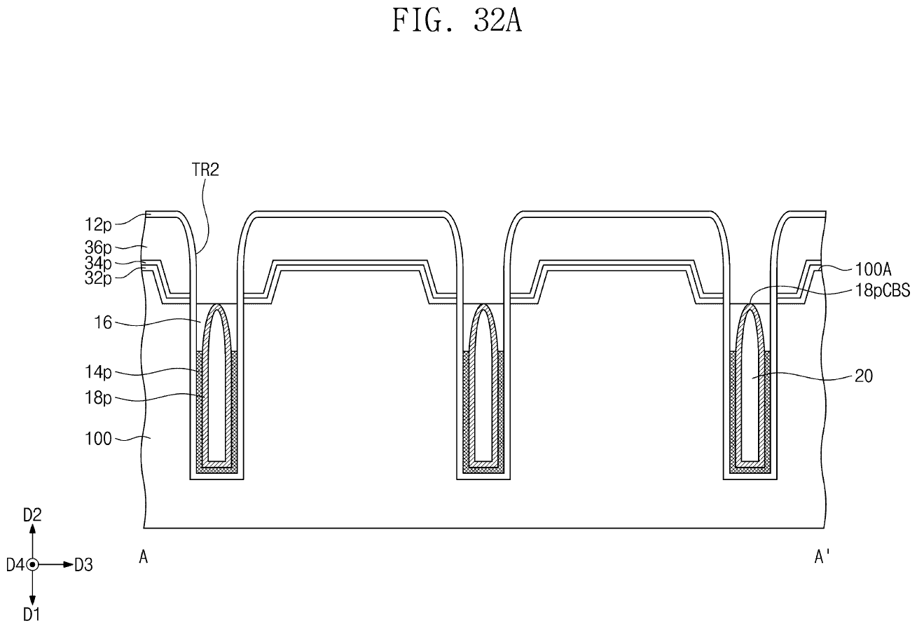

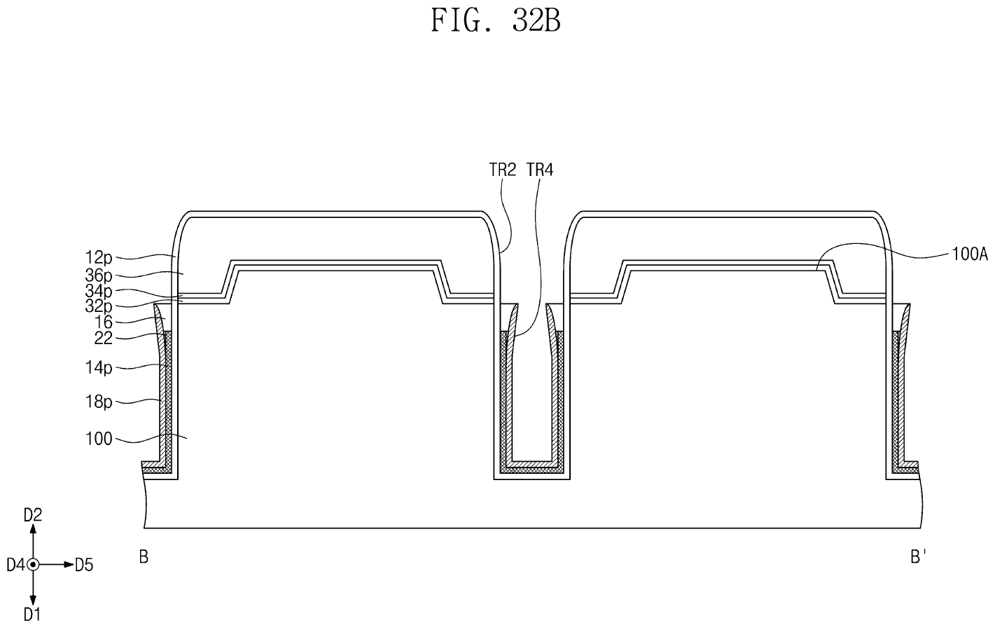

FIGS. 32A to 36A and FIGS. 32B to 36B are sectional views illustrating a method of fabricating an image sensor, according to some implementations and corresponding to the lines A-A′ and B-B′ of FIG. 4, respectively. For concise description, a previously described element may be identified by the same reference number without repeating an overlapping description thereof.

Referring to FIGS. 32A and 32B, the process may be performed identically as in FIGS. 29A and 29B. Thereafter, a portion of the preliminary gapfill insulating pattern 20L may be removed.

In the intervening region IR, the preliminary gapfill insulating pattern 20L may be removed such that it remains up to a level of a top surface of the preliminary conductive liner 18p. In the intervening region IR, the third space portion v3 may be filled with the preliminary gapfill insulating pattern 20L. In this case, the preliminary gapfill insulating pattern 20L interposed between the preliminary conductive liner 18p and the first insulating liner 12p may be defined as the underlying insulating layer 16. The preliminary gapfill insulating pattern 20L filling the third space portion v3 may be defined as the gapfill insulating pattern 20. The gapfill insulating pattern 20 may remain at the same level as the topmost portion 18pCBS of the preliminary conductive liner 18p.

In the intersecting region CR, the preliminary gapfill insulating pattern 20L may be removed such that it remains up to the level of the top surface of the preliminary conductive liner 18p. Thus, the underlying insulating layer 16 may be formed to be in contact with the preliminary conductive liner 18p, the intervening insulating pattern 22, and the first insulating liner 12p. The preliminary gapfill insulating pattern 20L may be removed to expose the second trench TR2.

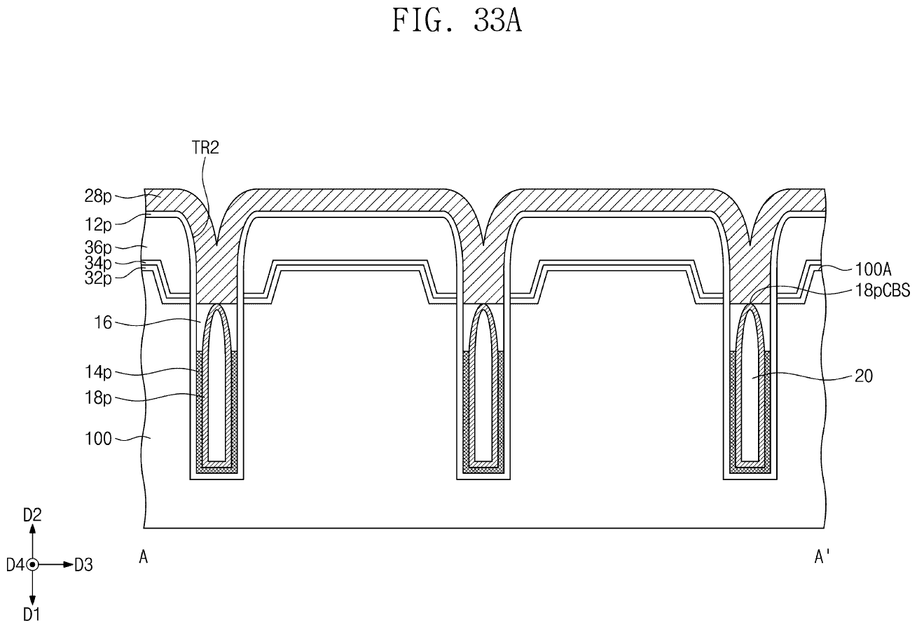

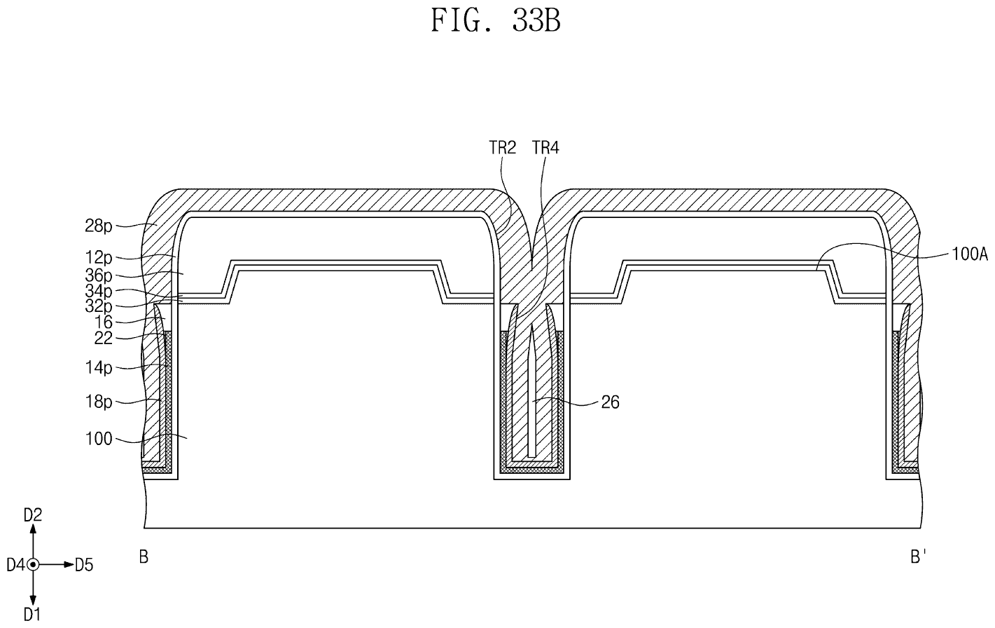

Referring to FIGS. 33A and 33B, in the intervening region IR, the preliminary gapfill layer 28p may be formed on the first insulating liner 12p. The preliminary gapfill layer 28p may be formed to cover the top surface of the underlying insulating layer 16 and to fill the second trench TR2.

In the intersecting region CR, the preliminary gapfill layer 28p may be formed to fill the entirety of the second trench TR2 and a portion of the fourth trench TR4, which is formed by the preliminary conductive liner 18p. Since the preliminary gapfill layer 28p does not fill a portion of the fourth trench TR4, the gap portion 26 may be formed.

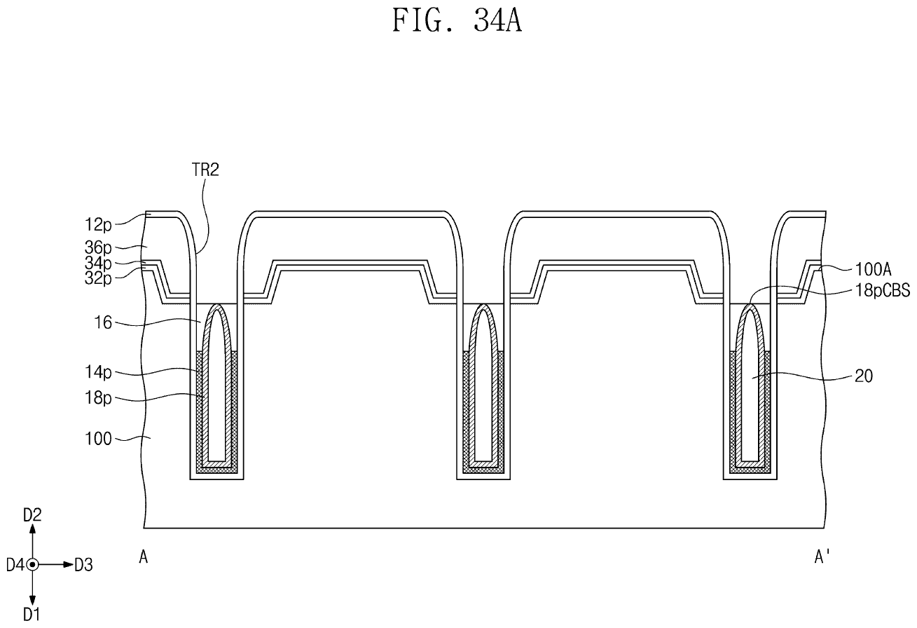

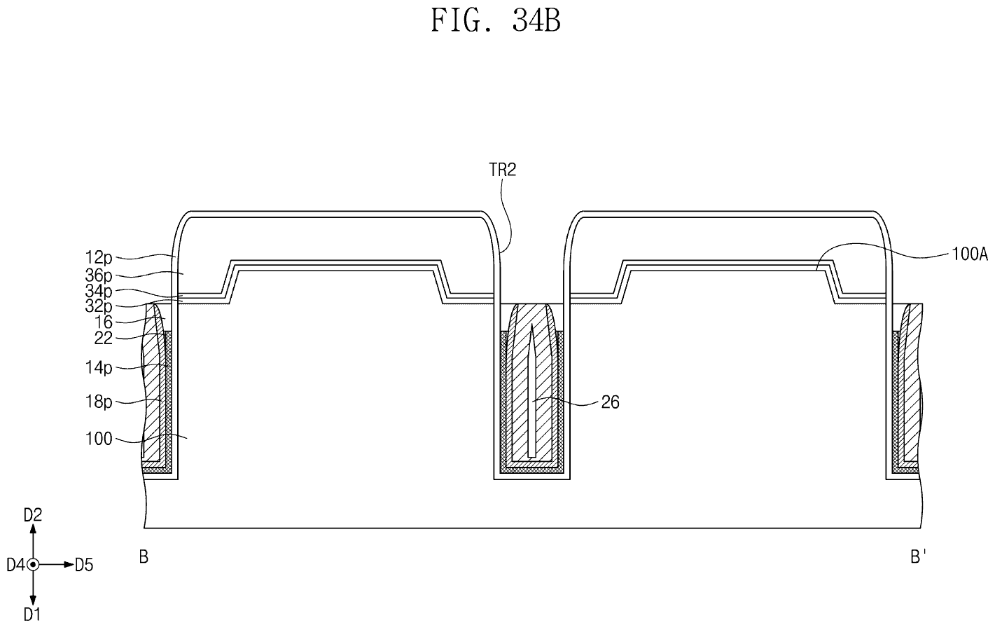

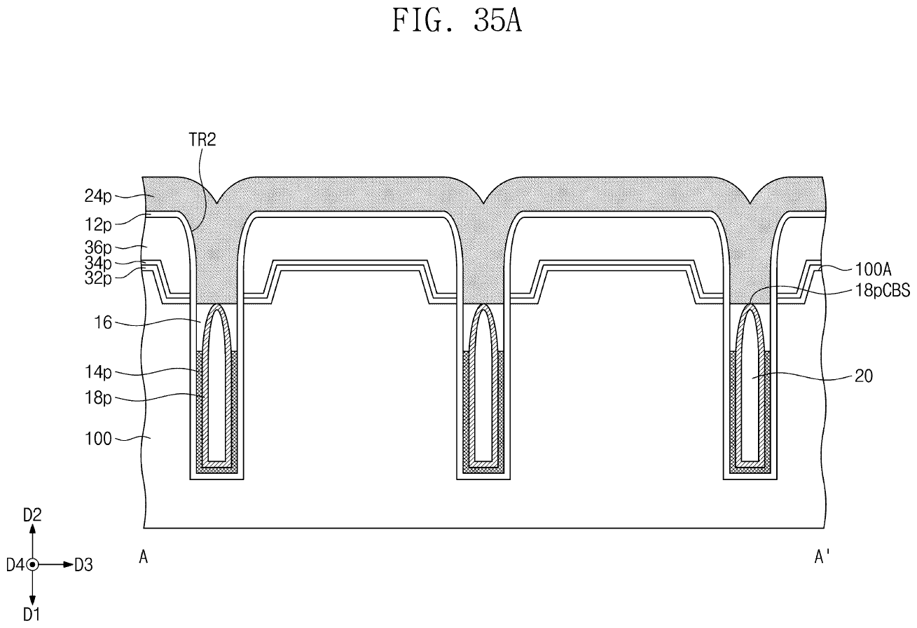

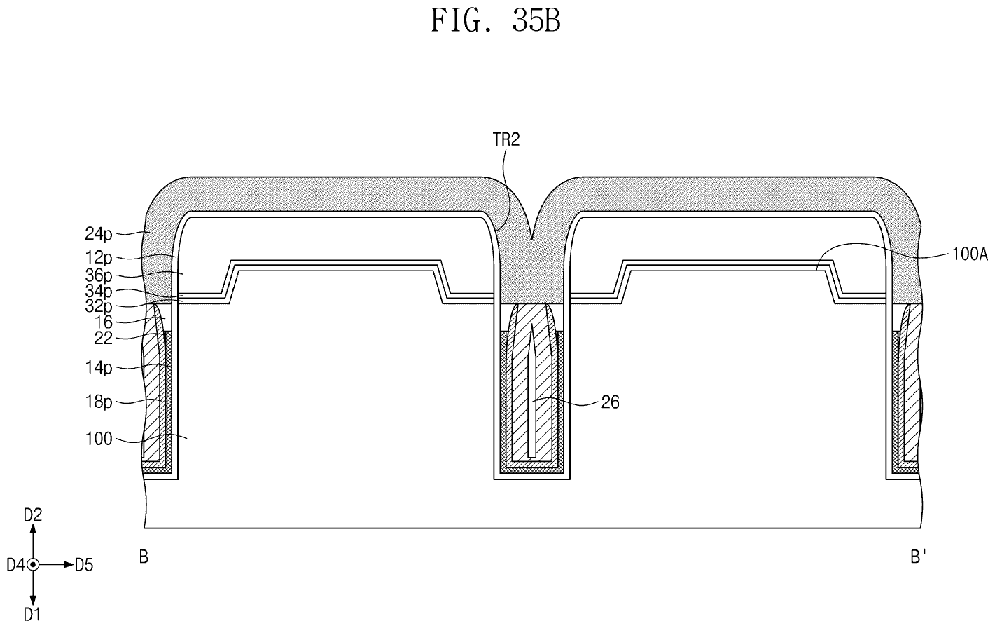

Referring to FIGS. 34A to 35A and 34B to 35B, the preliminary gapfill layer 28p may be removed. The preliminary inner insulating layer 24p may be formed, after the removal of the preliminary gapfill layer 28p.

In the intervening region IR, the preliminary gapfill layer 28p may be completely removed from the top surfaces of the first insulating liner 12p and the underlying insulating layer 16. The preliminary inner insulating layer 24p may be formed to cover a top surface of the first insulating liner 12p.

In the intersecting region CR, the preliminary gapfill layer 28p, which is located at a level higher than the top surface of the intervening insulating pattern 22, may be removed. Next, the preliminary inner insulating layer 24p may be formed to fill an inner surface of the second trench TR2, which is defined by an exposed top surface of the preliminary gapfill layer 28p and the first insulating liner 12p.

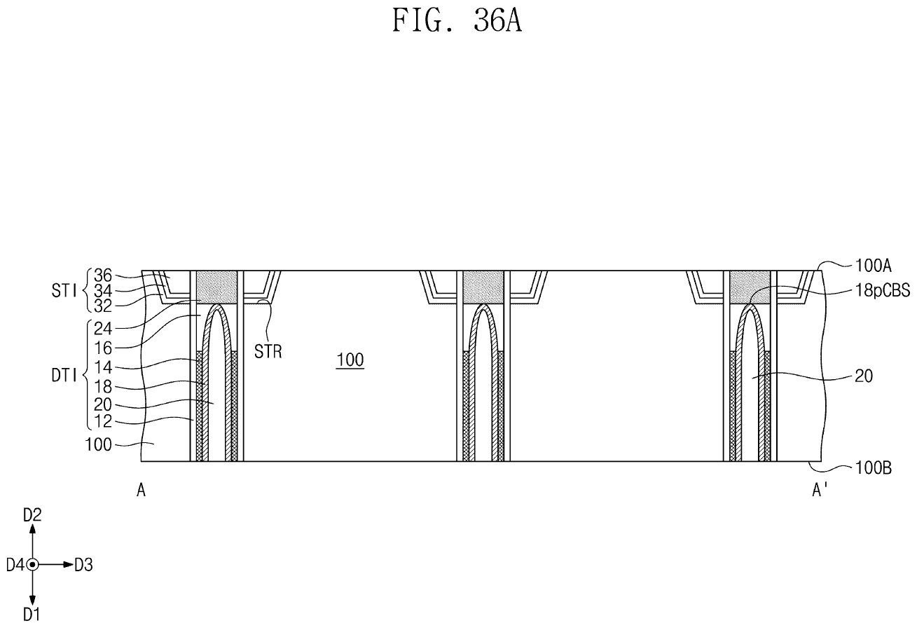

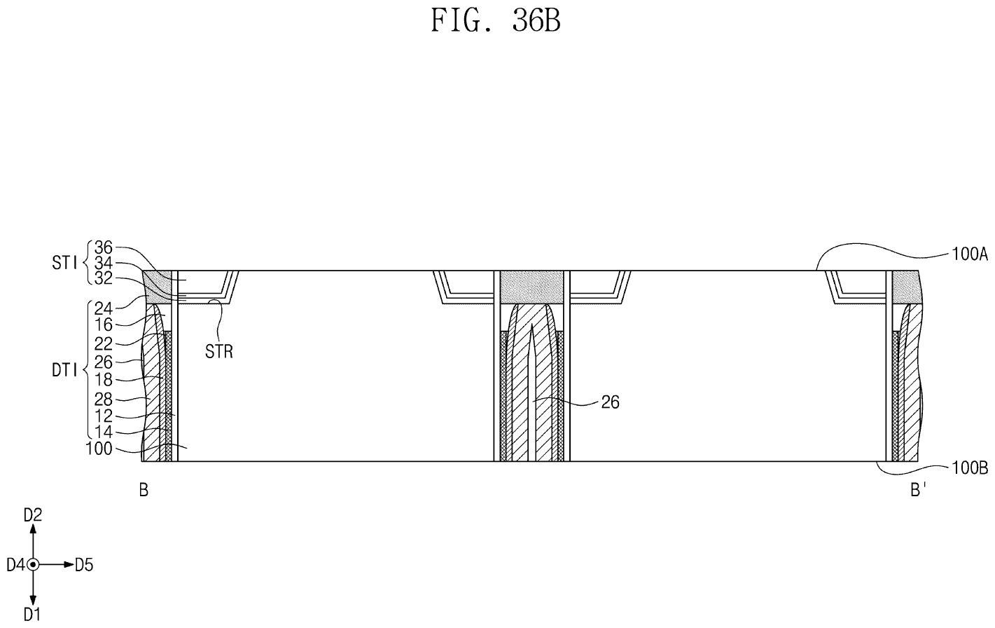

Referring to FIGS. 36A and 36B, a planarization process may be performed in a similar manner to the process described above. As a result, the image sensor may be fabricated to include the conductive liner 18, the second insulating liner 14, which is lower than the top surface of the conductive liner 18, and the underlying insulating layer 16 between the conductive liner 18 and the first surface 100A of the substrate 100. In this case, the image sensor may be formed to have the structure of FIGS. 9A and 9B.

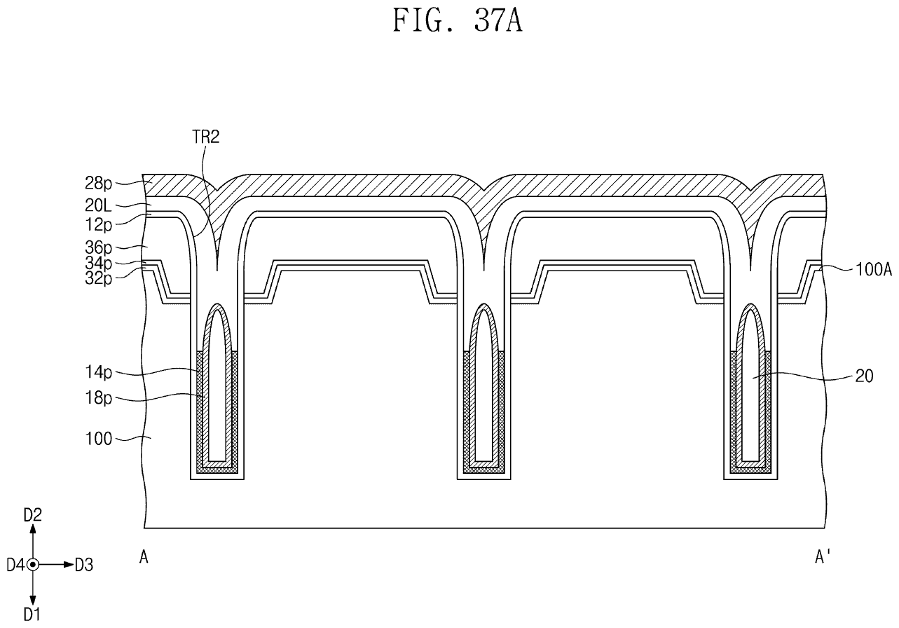

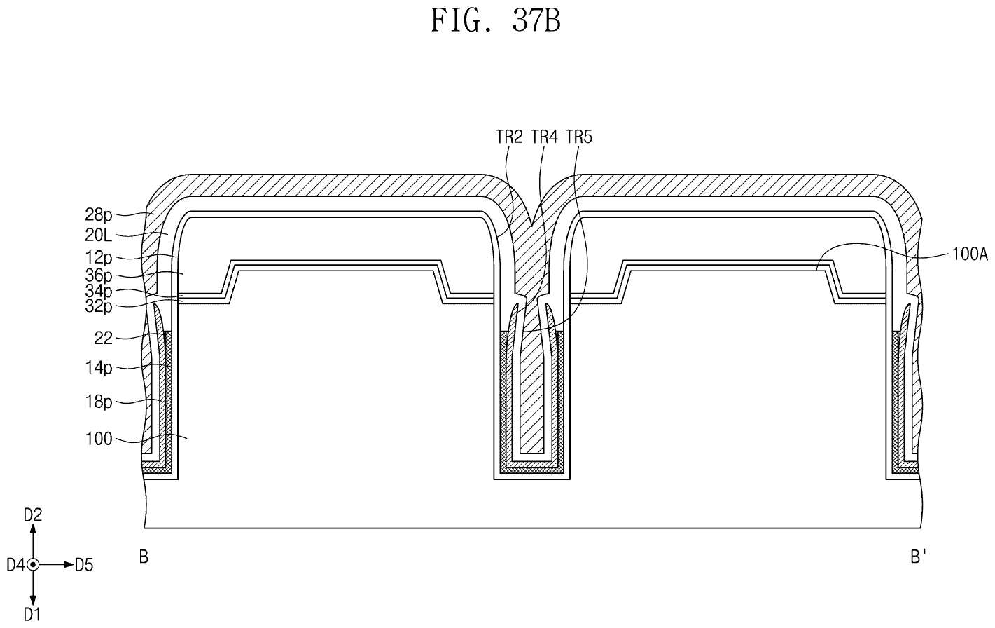

FIGS. 37A to 40A and FIGS. 37B to 40B are sectional views illustrating a method of fabricating an image sensor, according to some implementations and corresponding to the lines A-A′ and B-B′ of FIG. 4, respectively.

Referring to FIGS. 37A and 37B, the process may be performed identically as in FIGS. 29A and 29B. Next, the preliminary gapfill layer 28p may be formed on the structure with the preliminary gapfill insulating pattern 20L. The preliminary gapfill layer 28p may be formed to fully cover the top surface of the preliminary gapfill insulating pattern 20L.

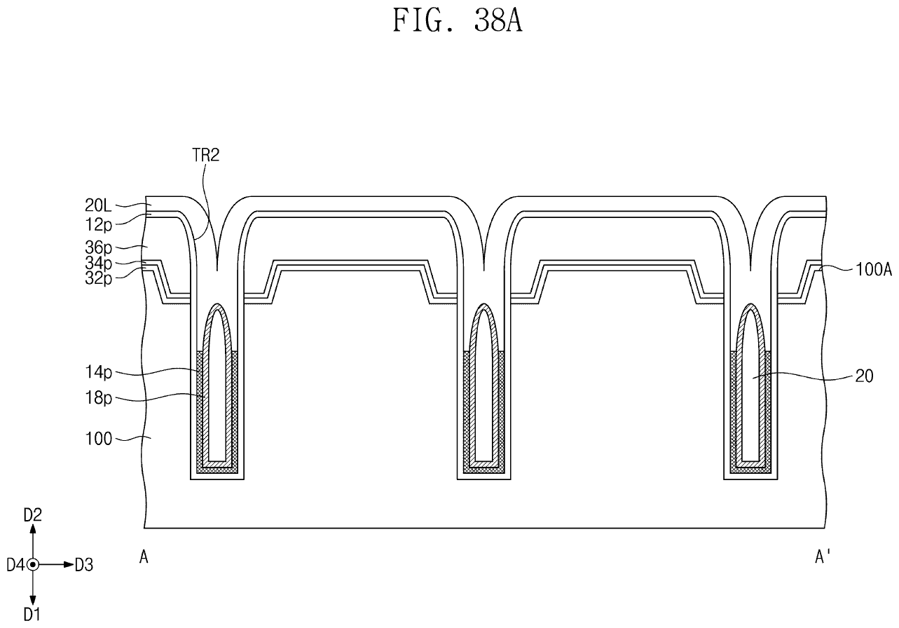

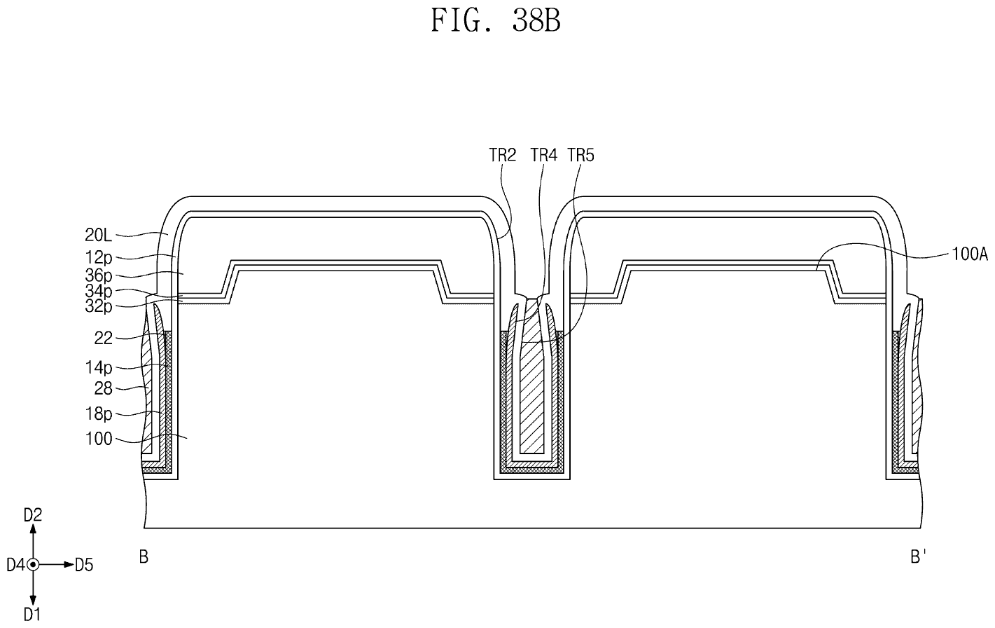

Referring to FIGS. 38A and 38B, the preliminary gapfill layer 28p may be removed. In the intervening region IR, the preliminary gapfill layer 28p may be fully removed. In the intersecting region CR, the preliminary gapfill layer 28p may be recessed to the same level as the top surface of the preliminary conductive liner 18p. As a result of the removal of the preliminary gapfill layer 28p, the top surface of the preliminary gapfill insulating pattern 20L may be exposed to the outside. A portion of the preliminary gapfill layer 28p may be removed to form the gapfill layer 28.

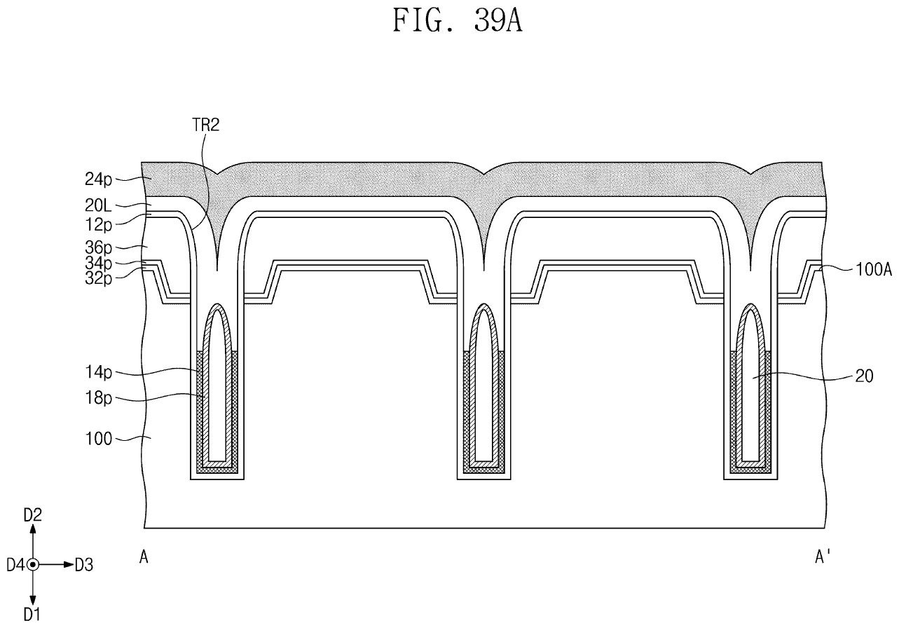

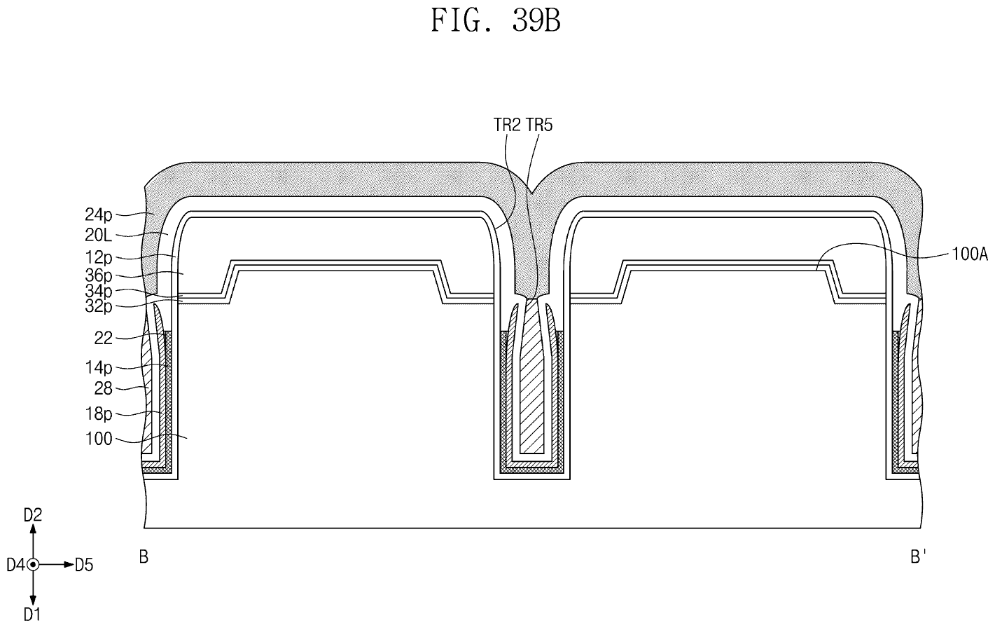

Referring to FIGS. 39A and 39B, the preliminary inner insulating layer 24p may be formed on the top surface of the preliminary gapfill insulating pattern 20L. The preliminary inner insulating layer 24p may be formed on the gapfill layer 28 and the preliminary gapfill insulating pattern 20L exposed to the outside.

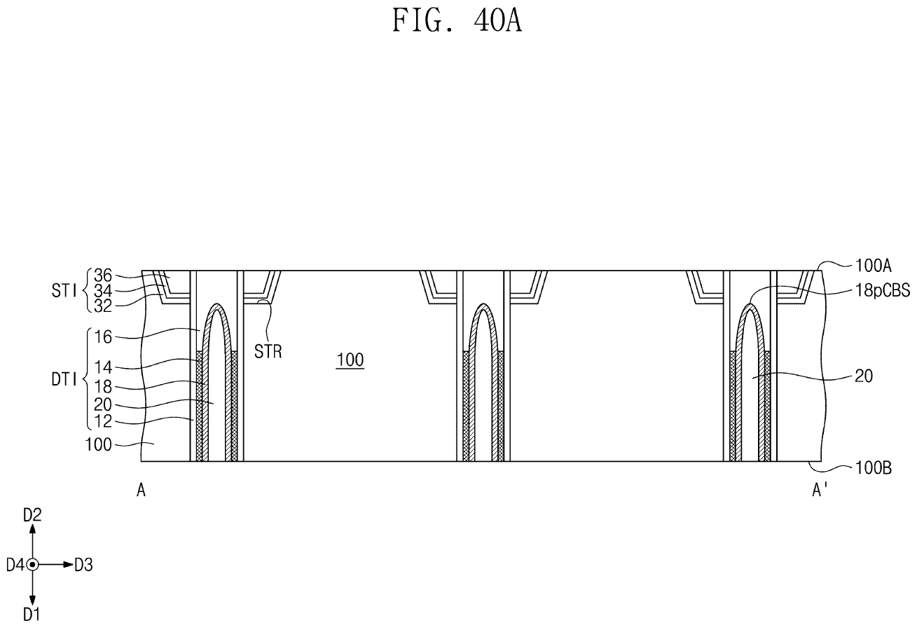

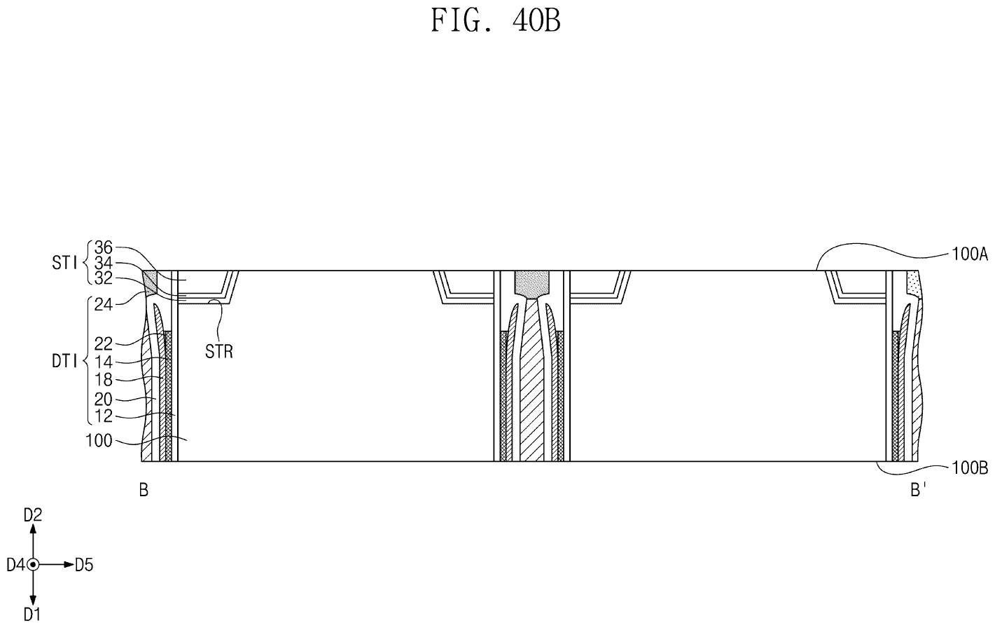

Referring to FIGS. 40A and 40B, a planarization process may be performed in a similar manner to the process described above. In this case, the image sensor may be formed to have the structure of FIGS. 10A and 10B.

According to some implementations, an image sensor may include a deep device isolation pattern, in which a conductive liner with a curved portion is provided. In this case, it may be possible to reduce a yield loss in a process of fabricating the deep device isolation pattern.

According to some implementations, in an image sensor, it may be possible to reduce a material with a high optical absorptivity. In this case, it may be possible to increase the sensitivity of the image sensor.

According to implementations, an image sensor may include a material having a high dielectric constant, and in this case, it may be possible to reduce a dark-level issue and a white spot issue in the image sensor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been particularly shown and described, it will be understood by one of ordinary skill in the art that variations in form and detail may be made therein without departing from the spirit and scope of the attached claims.

What is claimed is:

1. An image sensor, comprising:
a substrate having a first surface and a second surface, which are opposite to each other, and comprising a plurality of pixel regions; and
a device isolation pattern extending from the first surface into the substrate and interposed between the pixel regions,
wherein the device isolation pattern comprises an intervening region and an intersecting region,
in the intervening region, the device isolation pattern comprises:
a gapfill insulating pattern;
a conductive liner in contact with the gapfill insulating pattern;
an intervening insulating pattern in contact with the conductive liner;
a first insulating liner in contact with the substrate; and
a second insulating liner in contact with the intervening insulating pattern,
wherein an interface between the conductive liner and the intervening insulating pattern comprises a curved surface, and
a distance of the second insulating liner from the second surface of the substrate is 80% to 120% of a distance of a bottommost point of the conductive liner from the second surface of the substrate.

2. The image sensor of claim 1, wherein the first insulating liner comprises an oxide material, and
the second insulating liner comprises a nitride material.

3. The image sensor of claim 1, wherein, in the intersecting region, the device isolation pattern comprises:
a first insulating liner in contact with the substrate;
a second insulating liner on the first insulating liner;
a conductive liner in contact with the second insulating liner; and
an intervening insulating pattern in contact with the conductive liner and the second insulating liner,
wherein an outer side surface of the conductive liner is in contact with the second insulating liner and the intervening insulating pattern, and
an interface between the conductive liner and the intervening insulating pattern comprises a curved surface.

4. The image sensor of claim 3, wherein, in the intersecting region, the device isolation pattern further comprises a gapfill insulating pattern on the conductive liner,
in the intervening region, a distance from the second surface to a bottommost surface of the gapfill insulating pattern is smaller than a distance from the second surface to the bottommost point of the conductive liner, and
in the intersecting region, the gapfill insulating pattern is in contact with the second surface.

5. The image sensor of claim 1, wherein, in the intersecting region, the device isolation pattern comprises:
a first insulating liner in contact with the substrate;
a second insulating liner on the first insulating liner;
a conductive liner in contact with the second insulating liner;
a gapfill insulating pattern on the conductive liner; and
an intervening insulating pattern in contact with the conductive liner and the second insulating liner,
wherein the gapfill insulating pattern comprises a lower gapfill insulating pattern in contact with the first surface and an upper gapfill insulating pattern on the lower gapfill insulating pattern, and
the upper gapfill insulating pattern has an inclined side surface.

6. The image sensor of claim 1, wherein, in the intersecting region, the device isolation pattern comprises:
a gap portion defined in a center portion of the intersecting region;
an inner insulating pattern defining the gap portion;
a gapfill insulating pattern in contact with the inner insulating pattern; and
a conductive liner in contact with the gapfill insulating pattern,
wherein the gapfill insulating pattern comprises a lower gapfill insulating pattern in contact with the first surface of the substrate and an upper gapfill insulating pattern on the lower gapfill insulating pattern, and
an interface between the lower gapfill insulating pattern and the inner insulating pattern comprises a curved surface.

7. The image sensor of claim 1, wherein, in the intersecting region, the device isolation pattern comprises:
a first insulating liner in contact with the substrate;
a second insulating liner on the first insulating liner;
a conductive liner in contact with the second insulating liner; and
a gapfill layer on the conductive liner,
wherein the gapfill layer comprises a gap portion defined therein, and
the gap portion comprises an air gap or the same material as an anti-reflection layer.

8. The image sensor of claim 1, wherein, in the intersecting region, the device isolation pattern comprises:
a first insulating liner in contact with the substrate;
a second insulating liner on the first insulating liner;
a conductive liner in contact with the second insulating liner; and
an intervening insulating pattern in contact with the conductive liner and the second insulating liner,
wherein the intervening insulating pattern comprises a lower intervening insulating pattern in contact with the first surface and an upper intervening insulating pattern protruding from the lower intervening insulating pattern, and
an interface between the upper intervening insulating pattern and the conductive liner comprises a curved surface.

9. The image sensor of claim 1, wherein, in the intersecting region, the device isolation pattern comprises:
a first insulating liner in contact with the substrate;
a second insulating liner on the first insulating liner; and
a conductive liner in contact with the second insulating liner,
wherein a distance from the bottommost point of the conductive liner to the second surface is larger than a distance from a bottommost surface of the second insulating liner to the second surface.

10. An image sensor, comprising:
a substrate having a first surface and a second surface, which are opposite to each other, and comprising a plurality of pixel regions;
an anti-reflection layer on the substrate; and
a device isolation pattern extended from the first surface into the substrate and interposed between the pixel regions,
wherein the device isolation pattern comprises an intervening region and an intersecting region,
in the intersecting region, the device isolation pattern comprises:
a first insulating liner in contact with the substrate;
a second insulating liner on the first insulating liner;
a conductive liner in contact with the second insulating liner;
an intervening insulating pattern in contact with the conductive liner and the second insulating liner; and
a gap portion defined in a center portion of the intersecting region,
a bottom surface of the conductive liner comprises a curved surface, and
the gap portion comprises an air gap or the same material as the anti-reflection layer.

11. The image sensor of claim 10, wherein, in the intervening region, the device isolation pattern comprises:
a gapfill insulating pattern;
a conductive liner in contact with the gapfill insulating pattern;
an intervening insulating pattern in contact with the conductive liner;
a first insulating liner in contact with the substrate; and
a second insulating liner in contact with the intervening insulating pattern,
wherein a distance of a bottom surface of the second insulating liner from the second surface of the substrate is 80% to 120% of a distance of a bottommost point of the conductive liner from the second surface of the substrate.

12. The image sensor of claim 10, wherein, in the intervening region, the device isolation pattern comprises:
a gapfill insulating pattern;
a conductive liner in contact with the gapfill insulating pattern;
an intervening insulating pattern in contact with the conductive liner;
a first insulating liner in contact with the substrate; and
a second insulating liner in contact with the intervening insulating pattern,
wherein a distance of the second insulating liner from the second surface of the substrate is 10% to 75% of a distance of a bottommost point of the conductive liner from the second surface of the substrate.

13. The image sensor of claim 10, wherein the first insulating liner comprises a material that is etched by an HF solution, and
the second insulating liner comprises a material that resists being etched by the HF solution.

14. The image sensor of claim 10, further comprising a gapfill layer between the gap portion and the conductive liner, in the intersecting region,
wherein, in the intervening region, the device isolation pattern comprises a gapfill insulating pattern in contact with the second surface and a conductive liner enclosing the gapfill insulating pattern,
in the intersecting region, the conductive liner includes portions that are spaced apart from each other by the gapfill layer, and
in the intervening region, the conductive liner has a continuous structure.

15. The image sensor of claim 10, further comprising a shallow device isolation pattern that is disposed to be adjacent to the first surface of the substrate,
wherein, in the intervening region, the device isolation pattern further comprises:
an underlying insulating layer penetrating the shallow device isolation pattern;
a conductive liner on the underlying insulating layer; and
a gapfill insulating pattern surrounded by the conductive liner,
wherein the underlying insulating layer and the gapfill insulating pattern comprise the same material.

16. The image sensor of claim 10, wherein, in the intersecting region, the intervening insulating pattern comprises a lower intervening insulating pattern in contact with the first surface and an upper intervening insulating pattern protruding from the lower intervening insulating pattern, and
an interface between the upper intervening insulating pattern and the conductive liner comprises a curved surface.

17. The image sensor of claim 10, wherein, in the intersecting region, a distance from the second surface to a bottommost surface of the second insulating liner is smaller than a distance from the second surface to a bottommost point of the conductive liner.

18. An image sensor, comprising:
a substrate having a first surface and a second surface, which are opposite to each other, and comprising a plurality of pixel regions;
a transfer gate disposed on the first surface;
an anti-reflection layer disposed on the second surface;
color filters on the anti-reflection layer; and
a device isolation pattern extended from the first surface into the substrate and interposed between the pixel regions,
wherein the device isolation pattern comprises an intervening region and an intersecting region,
in the intervening region, the device isolation pattern comprises:
a gapfill insulating pattern;
a conductive liner in contact with the gapfill insulating pattern;
an intervening insulating pattern in contact with a bottom surface of the conductive liner;
a first insulating liner in contact with the substrate; and
a second insulating liner in contact with the intervening insulating pattern,
in the intersecting region, the device isolation pattern comprises:
a first insulating liner in contact with the substrate;
a second insulating liner on the first insulating liner;
a conductive liner in contact with the second insulating liner; and
a gap portion defined in a center portion of the intersecting region,
the bottom surface of the conductive liner comprises a curved surface, and
the first and second insulating liners comprise different materials having an different etching rates from each other.

19. The image sensor of claim 18, wherein, in the intersecting region, the device isolation pattern further comprises a gapfill layer interposed between the gap portion and the conductive liner, and
the gapfill layer comprises poly silicon.

20. The image sensor of claim 18, wherein a distance between a bottommost surface of the second insulating liner and the first surface of the substrate is larger than a distance between a bottommost point of the conductive liner and the first surface of the substrate and is smaller than a distance between a bottommost point of the gap portion and the first surface of the substrate.
